(19) United States
(12) Patent Application Publication
(10) Pub. No.: US 2024/0332101 A1
(43) Pub. Date: Oct. 3, 2024

(54) SEMICONDUCTOR DEVICE

(71) Applicant: ROHM CO., LTD., Kyoto-shi (JP)

(72) Inventor: Yusuke HARADA, Kyoto-shi (JP)

(21) Appl. No.: 18/743,964

(22) Filed: Jun. 14, 2024

Related U.S. Application Data
(63) Continuation of application No. PCT/JP2022/045145, filed on Dec. 7, 2022.

(30) Foreign Application Priority Data
Dec. 21, 2021 (JP) 2021-207462

(51) Int. Cl. H01L 23/29; H01L 23/00; H01L 23/31; H01L 23/498

(52) U.S. Cl. CPC H01L 23/29; H01L 23/3121; H01L 23/49838; H01L 24/29; H01L 24/32; H01L 2224/29111; H01L 2224/32225; H01L 2924/1815

(57) ABSTRACT

This semiconductor device comprises: a semiconductor element having an element surface, and an element rear surface on the opposite side from the element surface; an electrically conducting portion extending outward of the element rear surface from a position facing the element rear surface, and being electrically connected to the semiconductor element; and a sealing resin having a first sealing portion to which the electrically conducting portion is provided, and a second sealing portion that cooperates with the first sealing portion to seal the semiconductor element including the electrically conductive portion. The first sealing portion is constituted by a first material, and the second sealing portion is constituted by a second material. The Young's modulus of the second material is less than the Young's modulus of the first material.

### CROSS-REFERENCE TO RELATED APPLICATIONS

This application is a continuation of, and claims the benefit of priority from International Application No. PCT/JP2022/045145, filed on Dec. 7, 2022, which claims the benefit of priority from Japanese Patent Application No. 2021-207462, filed on Dec. 21, 2021, the entire contents of each of which are incorporated herein by reference.

### BACKGROUND

### 1. Field

The present disclosure relates to a semiconductor device.

### 2. Description of Related Art

Reduction in size of recent electronic apparatuses is promoting reduction in size of a semiconductor device used for the electronic apparatuses. There have been proposals to use a fan-out type semiconductor device, which includes conductors electrically connected to a semiconductor element and extending outward from the semiconductor element (refer to, for example, Japanese Laid-Open Patent Publication No. 2021-93454). The fan-out type semiconductor device is reduced in size and demonstrates increased flexibility in the shape of wiring patterns of a circuit board on which the semiconductor device is mounted.

An example of such a semiconductor device includes an encapsulation resin encapsulating the conductors and the semiconductor element and a thermal pad arranged to overlap the semiconductor element as viewed in the thickness-wise direction of the encapsulation resin. The thermal pad is exposed from a back surface of the encapsulation resin.

### BRIEF DESCRIPTION OF DRAWINGS

FIG. 1 is a perspective view showing an embodiment of a semiconductor device.

FIG. 2 is a schematic plan view showing an encapsulation resin and interconnect portions in the semiconductor device shown in FIG. 1.

FIG. 3 is a schematic cross-sectional view of the semiconductor device taken along line F3-F3 in FIG. 2.

FIG. 4 is a back view of the semiconductor device shown in FIG. 1.

FIG. 5 is a schematic diagram showing an example of a step of manufacturing the semiconductor device of the first embodiment.

FIG. 6 is a schematic diagram showing an example of a step of manufacturing the semiconductor device following the step shown in FIG. 5.

FIG. 7 is a schematic diagram showing an example of a step of manufacturing the semiconductor device following the step shown in FIG. 6.

FIG. 8 is a schematic diagram showing an example of a step of manufacturing the semiconductor device following the step shown in FIG. 7.

FIG. 9 is a schematic diagram showing an example of a step of manufacturing the semiconductor device following the step shown in FIG. 8.

FIG. 10 is a schematic diagram showing an example of a step of manufacturing the semiconductor device following the step shown in FIG. 9.

FIG. 11 is a schematic diagram showing an example of a step of manufacturing the semiconductor device following the step shown in FIG. 10.

FIG. 12 is a schematic diagram showing an example of a step of manufacturing the semiconductor device following the step shown in FIG. 11.

FIG. 13 is a schematic diagram showing an example of a step of manufacturing the semiconductor device following the step shown in FIG. 12.

FIG. 14 is a schematic diagram showing an example of a step of manufacturing the semiconductor device following the step shown in FIG. 13.

FIG. 15 is a graph showing thermal stress in a pillar portion of an electrical conductor and flexural strength of a first encapsulation portion in experimental examples 1 to 4.

FIG. 16 is a graph showing thermal stress in an interconnect portion of an electrical conductor and flexural strength of a second encapsulation portion in experimental examples 1 to 4.

FIG. 17 is a schematic cross-sectional view showing a second embodiment of a semiconductor device.

FIG. 18 is a schematic diagram showing an example of a step of manufacturing the semiconductor device of the second embodiment.

FIG. 19 is a schematic diagram showing an example of a step of manufacturing the semiconductor device following the step shown in FIG. 18.

FIG. 20 is a schematic diagram showing an example of a step of manufacturing the semiconductor device following the step shown in FIG. 19.

FIG. 21 is a schematic diagram showing an example of a step of manufacturing the semiconductor device following the step shown in FIG. 20.

### DETAILED DESCRIPTION

Embodiments of a semiconductor device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

### Structure of Semiconductor Device

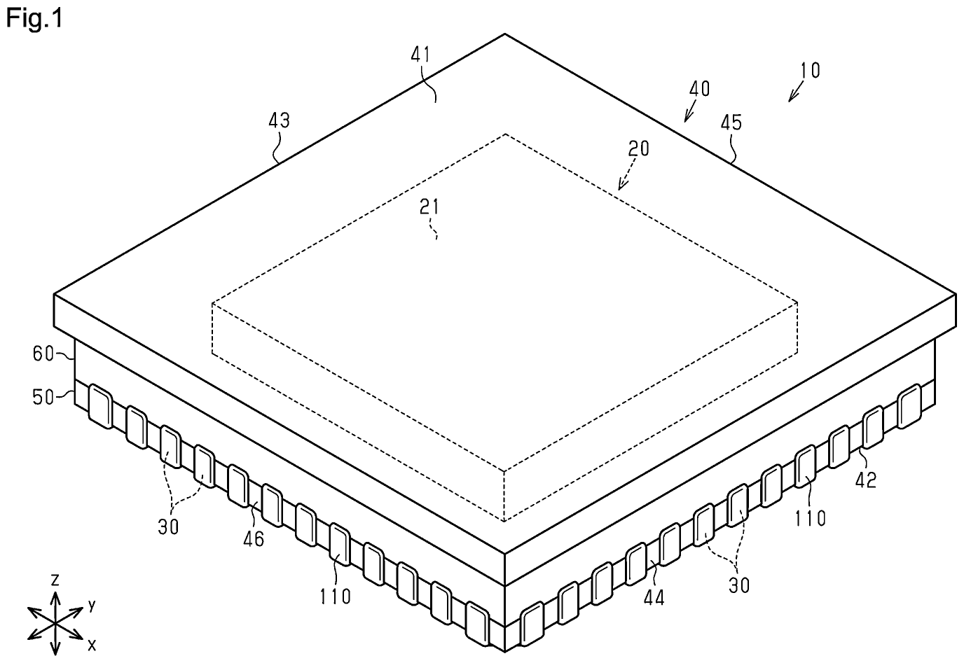

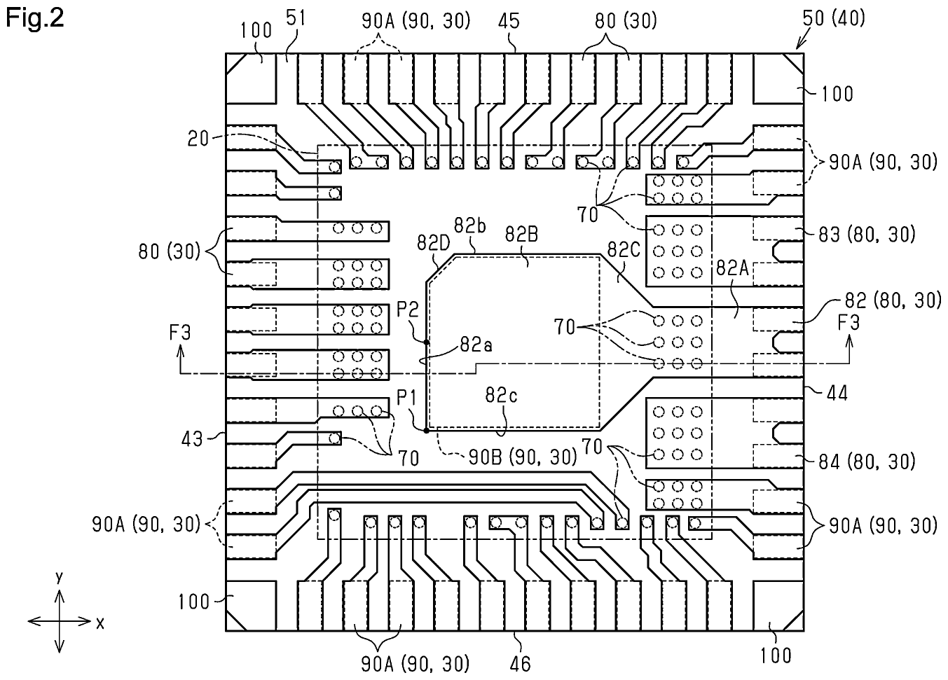

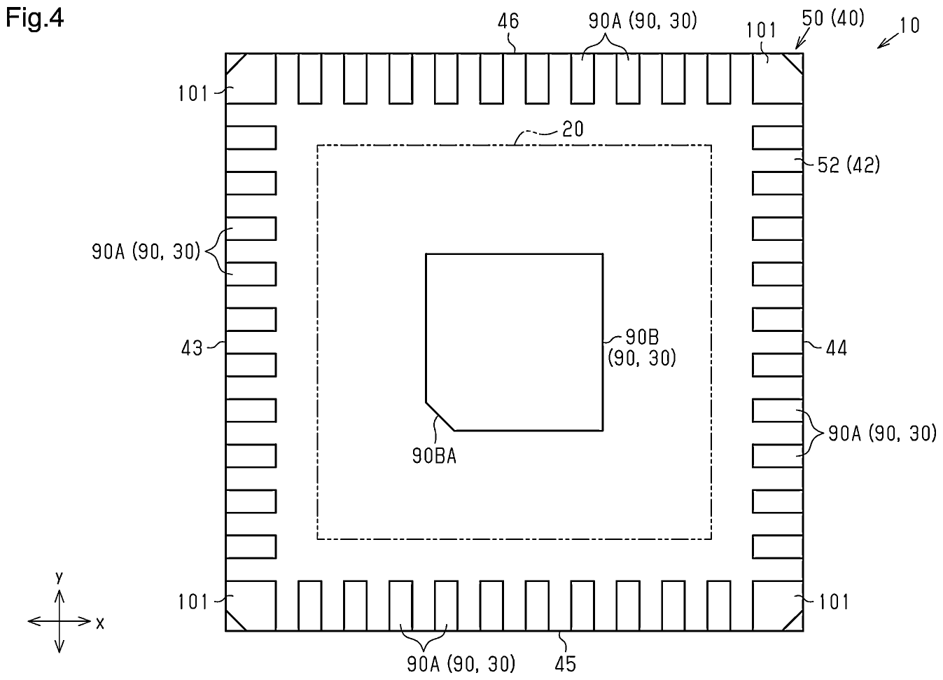

The structure of a first embodiment of a semiconductor device 10 will now be described with reference to FIGS. 1 to 4. In FIG. 2, a semiconductor element 20 and bonding layer pieces 70, which will be described later, are indicated by double-dashed lines for the sake of convenience. Also, FIG. 2 does not show part of an encapsulation resin 40, which will be described later, for the sake of convenience. FIG. 4 does not show a conductive film 110, which will be described later, for the sake of convenience.

As shown in FIGS. 1 to 3, a semiconductor device 10 includes a semiconductor element 20, electrical conductors 30 electrically connected to the semiconductor element 20, and an encapsulation resin 40 encapsulating the semiconductor element 20 and the electrical conductors 30. The semiconductor device 10 is configured to be surface-mounted on a circuit board (not shown) of various electronic apparatuses. The semiconductor device 10 has a package structure of a surface mount type.

As shown in FIG. 1, the encapsulation resin 40 includes an outer surface of the semiconductor device 10. The encapsulation resin 40 has the form of a substantially rectangular plate. In other words, the semiconductor device 10 has the form of a substantially rectangular plate. For the sake of brevity, the thickness-wise direction of the encapsulation resin 40 is referred to as a z-direction. Hence, “viewed in the z-direction” has the meaning of “viewed in the thickness-wise direction of the encapsulation resin 40.” As viewed in the z-direction, a direction extending along one side of the semiconductor device 10 orthogonal to the z-direction is referred to as an x-direction, and a direction orthogonal to the x-direction and the z-direction is referred to as a y-direction. In the present embodiment, as viewed in the z-direction, the y-direction also extends along one side of the semiconductor device 10.

In the present embodiment, the encapsulation resin 40 is square as viewed in the z-direction. In other words, the semiconductor device 10 is square as viewed in the z-direction. The shape of the encapsulation resin 40 (the shape of the semiconductor device 10) may be changed in any manner. In an example, as viewed in the z-direction, the encapsulation resin 40 (semiconductor device 10) may be rectangular such that the sides in the x-direction are longer than the sides in the y-direction or the sides in the y-direction are longer than the sides in the x-direction.

The encapsulation resin 40 includes a resin front surface 41 and a resin back surface 42 opposite to the resin front surface 41. The encapsulation resin 40 further includes four resin side surfaces joining the resin front surface 41 and the resin back surface 42 in the z-direction, namely, a first resin side surface 43, a second resin side surface 44, a third resin side surface 45, and a fourth resin side surface 46.

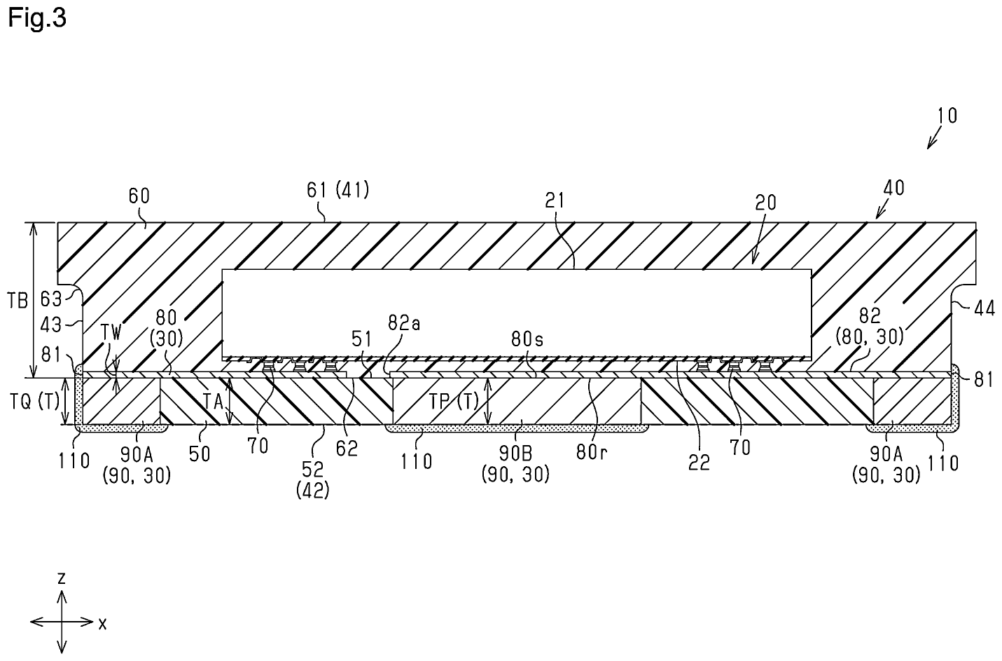

As shown in FIG. 3, the encapsulation resin 40 includes a first encapsulation portion 50 and a second encapsulation portion 60 formed on the first encapsulation portion 50. Each of the first encapsulation portion 50 and the second encapsulation portion 60 is formed from an insulative material.

The first encapsulation portion 50 is a support member used as a base of the semiconductor device 10. The semiconductor element 20 is mounted on the first encapsulation portion 50. The first encapsulation portion 50 forms a portion of the encapsulation resin 40 located toward the resin back surface 42. The first encapsulation portion 50 includes a first encapsulation front surface 51 facing the same direction as the resin front surface 41 and a first encapsulation back surface 52 defining the resin back surface 42. The first encapsulation portion 50 includes first encapsulation side surfaces defining portions of the first to fourth resin side surfaces 43 to 46. The first encapsulation front surface 51 is formed of a cut surface, which will be described later in a method of manufacturing the semiconductor device 10.

The second encapsulation portion 60 is a second encapsulation member that encapsulates the semiconductor element 20. The second encapsulation portion 60 encapsulates the electrical conductors 30 and the semiconductor element 20 in cooperation with the first encapsulation portion 50. The second encapsulation portion 60 forms a portion of the encapsulation resin 40 located toward the resin front surface 41. The second encapsulation portion 60 includes a second encapsulation front surface 61 defining the resin front surface 41 and a second encapsulation back surface 62 opposite to the second encapsulation front surface 61. The second encapsulation back surface 62 is in contact with the first encapsulation front surface 51 of the first encapsulation portion 50. The second encapsulation portion 60 includes second encapsulation side surfaces defining portions of the first to fourth resin side surfaces 43 to 46.

The first encapsulation portion 50 and the second encapsulation portion 60 are formed integrally. Since the first encapsulation front surface 51 is formed of the cut surface, an interface is formed in the boundary between the first encapsulation portion 50 and the second encapsulation portion 60. The boundary between the first encapsulation portion 50 and the second encapsulation portion 60, defining the interface, is formed of the first encapsulation front surface 51 of the first encapsulation portion 50 and the second encapsulation back surface 62 of the second encapsulation portion 60.

Each encapsulation side surface of the second encapsulation portion 60 is recessed inward to include a step 63. In the present embodiment, the step 63 overlaps the semiconductor element 20 as viewed in a direction orthogonal to the z-direction.

The first encapsulation portion 50 has a thickness TA that is smaller than a thickness TB of the second encapsulation portion 60. In the present embodiment, the thickness TA of the first encapsulation portion 50 is smaller than the thickness of the semiconductor element 20. In an example, the thickness TA of the first encapsulation portion 50 is less than or equal to 100 μm. Preferably, the thickness TA of the first encapsulation portion 50 is in a range of 40 μm to 70 μm. In the present embodiment, the thickness TA of the first encapsulation portion 50 is approximately 55 μm. The thickness TA of the first encapsulation portion 50 is defined by the dimension between the first encapsulation front surface 51 and the first encapsulation back surface 52 in the z-direction. The thickness TB of the second encapsulation portion 60 is defined by the dimension between the second encapsulation front surface 61 and the second encapsulation back surface 62 in the z-direction. The thickness of the semiconductor element 20 is defined by the dimension in the z-direction between an element front surface 21 and an element back surface 22, which will be described later.

The semiconductor element 20 encapsulated in the second encapsulation portion 60 is, for example, an integrated circuit (IC) such as a large scale integration (LSI). The semiconductor element 20 may be a voltage-controlling element such as a low dropout (LDO) regulator, an amplifying element such as an operational amplifier, or a discrete semiconductor element such as a diode or various sensors.

As shown in FIG. 1, the semiconductor element 20 is flat. In the present embodiment, the semiconductor element 20 is square as viewed in the z-direction. The shape of the semiconductor element 20 as viewed in the z-direction may be changed in any manner.

In an example, as viewed in the z-direction, the semiconductor element 20 may be rectangular such that the sides in the x-direction are longer than the sides in the y-direction or the sides in the y-direction are longer than the sides in the x-direction.

As shown in FIG. 3, the semiconductor element 20 includes an element front surface 21 and an element back surface 22 opposite to the element front surface 21. The element front surface 21 faces the same direction as the resin front surface 41. In other words, the resin front surface 41 faces the same direction as the element front surface 21. The element back surface 22 faces the same direction as the resin back surface 42. In other words, the element back surface 22 is opposed to the first encapsulation front surface 51 of the first encapsulation portion 50. The semiconductor element 20 further includes four element side surfaces joining the element front surface 21 and the element back surface 22 in the z-direction. The semiconductor element 20 is entirely covered by the encapsulation resin 40 (second encapsulation portion 60). The phrase “viewed in the z-direction” includes the meaning of “viewed from the element front surface 21.”

As shown in FIG. 3, the electrical conductors 30 extend outward from a position opposed to the element back surface 22 of the semiconductor element 20 as viewed in the z-direction beyond the element back surface 22. In the present embodiment, the electrical conductors 30 are formed of a plating layer. The electrical conductors 30 each include an interconnect portion 80 and a pillar portion 90. In the present embodiment, the interconnect portions 80 and the pillar portions 90 are formed separately.

The interconnect portions 80 are formed on the first encapsulation portion 50. More specifically, the interconnect portions 80 are formed on the first encapsulation front surface 51 of the first encapsulation portion 50. Since the first encapsulation front surface 51 is a flat surface orthogonal to the z-direction, the interconnect portions 80 extend in a direction orthogonal to the z-direction. The interconnect portions 80 each include an interconnect front surface 80s and an interconnect back surface 80r. The interconnect front surface 80s and the element front surface 21 of the semiconductor element 20 face the same direction. The interconnect back surface 80r and the interconnect front surface 80s face opposite directions. In the present embodiment, the interconnect front surface 80s is located closer to the semiconductor element 20 than the interface between the first encapsulation portion 50 and the second encapsulation portion 60 in the z-direction. The interconnect back surface 80r is in contact with the first encapsulation front surface 51 of the first encapsulation portion 50. Thus, the interconnect back surface 80r is aligned with the interface between the first encapsulation portion 50 and the second encapsulation portion 60 in the z-direction.

As shown in FIGS. 2 and 3, the interconnect portions 80 are located at a position opposed to the element back surface 22 of the semiconductor element 20. As viewed in the z-direction, the interconnect portions 80 extend outward from the position opposed to the element back surface 22 of the semiconductor element 20 beyond the semiconductor element 20. In other words, the interconnect portions 80 each include an extension extending out from the semiconductor element 20 as viewed in the z-direction.

As shown in FIG. 3, the interconnect portions 80 have the same thickness TW. The thickness TW of the interconnect portion 80 is smaller than the thickness TA of the first encapsulation portion 50. The thickness TW of the interconnect portion 80 is smaller than ½ of the thickness TA of the first encapsulation portion 50. The thickness TW of the interconnect portion 80 is less than or equal to ⅓ of the thickness TA of the first encapsulation portion 50. The thickness TW of the interconnect portion 80 is greater than or equal to ¼ of the thickness TA of the first encapsulation portion 50. In an example, the thickness TW of the interconnect portion 80 is less than 30 μm. Preferably, the thickness TW of the interconnect portion 80 is in a range of 15 μm to 20 μm. In the present embodiment, the thickness TW of the interconnect portion 80 is approximately 15 μm.

Although not shown, the interconnect portion 80 is formed of a plating layer and includes a metal layer and a main interconnect layer. The metal layer is formed as a seed layer for forming the main interconnect layer. The metal layer is formed from a material including, for example, titanium (Ti). In the present embodiment, the metal layer includes a Ti layer and a copper (Cu) layer in contact with the Ti layer. The metal layer is formed on the first encapsulation front surface 51 of the first encapsulation portion 50. More specifically, the Ti layer is formed on the first encapsulation front surface 51. The Cu layer is formed on the Ti layer. Thus, the metal layer is formed on the first encapsulation front surface 51.

The main interconnect layer is formed on the metal layer. More specifically, the main interconnect layer is formed on the Cu layer of the metal layer. In other words, the interconnect portion 80 has a stacking structure of the metal layer and the main interconnect layer. The main interconnect layer is formed from, for example, Cu or an alloy including Cu.

As shown in FIG. 2, as viewed in the z-direction, each interconnect portion 80 extends toward one of the first to fourth resin side surfaces 43 to 46 from a position where the interconnect portion 80 overlaps the semiconductor element 20. Each interconnect portion 80 is exposed from the resin side surface corresponding to the interconnect portion 80. In other words, as shown in FIG. 3, each interconnect portion 80 includes an exposed interconnect side surface 81 exposed from the resin side surface corresponding to the interconnect portion 80. In the present embodiment, the exposed interconnect side surface 81 is flush with the resin side surface.

The resin side surface corresponding to the interconnect portion 80 refers to the resin side surface that is located closest to the interconnect portion 80. The resin side surface corresponding to the interconnect portion 80 also refers to the resin side surface on which the exposed interconnect side surface 81 of the interconnect portion 80 is formed.

As shown in FIG. 2, the interconnect portions 80 include an interconnect portion 82 extending from the second resin side surface 44 to the center of the first encapsulation portion 50 (encapsulation resin 40). The interconnect portion 82 includes a part that is wider than the other interconnect portions 80. The interconnect portion 82 may be divided into an outer part 82A located toward the second resin side surface 44, an inner part 82B located toward the center of the first encapsulation front surface 51, and a joining part 82C joining the outer part 82A and the inner part 82B.

The outer part 82A extends from the second resin side surface 44 toward the center of the first encapsulation front surface 51 in the x-direction. As viewed in the z-direction, the outer part 82A may be divided into a first section overlapping the semiconductor element 20 and a second section extending from the first section beyond the semiconductor element 20. The outer part 82A has a width-wise dimension (dimension of the outer part 82A in the y-direction) that is equal to a width-wise dimension of interconnect portions 83 and 84 located next to the outer part 82A in the y-direction (dimension of the interconnect portions 83 and 84 in the y-direction). The width-wise dimension of the interconnect portions 83 and 84 is larger than a width-wise dimension of the interconnect portions 80 excluding the interconnect portions 82 to 84 (dimension of the interconnect portions 80 in a short-side direction). The outer part 82A includes the exposed interconnect side surface 81.

As viewed in the z-direction, the inner part 82B overlaps the semiconductor element 20. The inner part 82B is located closer to the center of the encapsulation resin 40 than the other interconnect portions 80 are. Thus, the interconnect portion 82 is greater than the interconnect portions 83 and 84 in dimension in the x-direction. The inner part 82B has a width-wise dimension (dimension of the inner part 82B in the y-direction) that is larger than the width-wise dimension of the outer part 82A. The width-wise dimension of the inner part 82B is smaller than the dimension of the interconnect portion 82 in the x-direction. As viewed in the x-direction, the inner part 82B partially overlaps the interconnect portions 83 and 84. As viewed in the z-direction, the inner part 82B is greater in area than the interconnect portions 83 and 84.

As viewed in the z-direction, the inner part 82B includes a distal surface 82a extending in a direction orthogonal to the direction (x-direction) in which the interconnect portion 82 extends, and a first end surface 82b and a second end surface 82c defining two end surfaces of the inner part 82B in the y-direction. The distal surface 82a is the one of the surfaces of the interconnect portion 82 that is located closest to the first resin side surface 43. The first end surface 82b is the one of the two end surfaces of the inner part 82B in the y-direction that is located closer to the third resin side surface 45. The second end surface 82c is the one of the two end surfaces of the inner part 82B in the y-direction that is located closer to the fourth resin side surface 46. The distal surface 82a has a position P2 located at the center of the resin back surface 42 in the y-direction.

The inner part 82B includes a slope 82D arranged between the distal surface 82a and the first end surface 82b. As the slope 82D extends from the first resin side surface 43 toward the second resin side surface 44, the slope 82D is inclined toward the third resin side surface 45.

In the inner part 82B, the distal surface 82a is orthogonally joined to the second end surface 82c. In other words, the corner of the inner part 82B located toward the first resin side surface 43 and the fourth resin side surface 46 is a right angle. In the present embodiment, as viewed in the z-direction, the intersection of the distal surface 82a and the second end surface 82c is referred to as a position P1.

The joining part 82C is arranged between the outer part 82A and the inner part 82B in the x-direction. The joining part 82C is tapered so that the width increases from the outer part 82A toward the inner part 82B.

The semiconductor element 20 is connected to the interconnect portions 80 by the conductive bonding layer pieces 70. The bonding layer pieces 70 electrically connect the semiconductor element 20 to the interconnect portions 80. The bonding layer pieces 70 are arranged between the semiconductor element 20 and the interconnect portions 80 in the z-direction to bond the semiconductor element 20 and the interconnect portions 80. The bonding layer pieces 70 include a solder layer. The bonding layer pieces 70 are formed of tin (Sn) or an alloy including Sn. The alloy including Sn includes, for example, a tin-silver (Ag)-based alloy and a tin-antimony (Sb)-based alloy.

As shown in FIG. 2, multiple bonding layer pieces 70 may be arranged on a single interconnect portion 80, or a single bonding layer piece 70 may be arranged on the interconnect portion 80. In the present embodiment, a greater number of bonding layer pieces 70 is arranged on each of the interconnects 82 to 84 than on the other interconnect portions 80. The number of the bonding layer pieces 70 arranged on each interconnect portion 80 is set, for example, in accordance with the amount of current flowing through the interconnect portion 80.

As shown in FIG. 3, in the present embodiment, the pillar portions 90 extend through the first encapsulation portion 50 in the z-direction. The pillar portions 90 are formed from the same material as the main interconnect layer of the interconnect portions 80 and, in the present embodiment, are formed from a material including Cu. As shown in FIG. 4, in the present embodiment, the pillar portions 90 include external connection terminals 90A and a thermal pad 90B.

The external connection terminals 90A form part of the electrical conductors 30 and are electrically connected to the semiconductor element 20 by the interconnect portions 80 (refer to FIG. 2). As shown in FIG. 4, the external connection terminals 90A are arranged on an outermost peripheral portion of the resin back surface 42. Thus, the external connection terminals 90A are located outward from the semiconductor element 20. As described above, the semiconductor device 10 of the present embodiment is of a fan-out type in which the external connection terminals 90A are located outward from the semiconductor element 20. As shown in FIGS. 3 and 4, the external connection terminals 90A are exposed from the resin back surface 42 and one of the first to fourth resin side surfaces 43 to 46. The external connection terminals 90A are formed from, for example, Cu or an alloy including Cu. The external connection terminals 90A are formed by, for example, electrolytic plating.

As viewed in the z-direction, each of the external connection terminals 90A is rectangular and includes long sides and short sides. The short sides of the external connection terminal 90A extend in an arrangement direction of the external connection terminals 90A. The long sides extend in a direction orthogonal to the arrangement direction as viewed in the z-direction.

As shown in FIG. 3, the external connection terminals 90A are connected to the interconnect portions 80. The external connection terminals 90A are arranged on the first encapsulation portion 50 and extend from the interconnect portions 80 toward the resin back surface 42. The external connection terminals 90A are covered by the interconnect portions 80 in the z-direction and thus do not project from the first encapsulation front surface 51 of the first encapsulation portion 50 toward the resin front surface 41. Also, the external connection terminals 90A do not project from the first encapsulation back surface 52 (resin back surface 42) of the first encapsulation portion 50 in a direction away from the first encapsulation front surface 51. Therefore, the external connection terminals 90A have a thickness TQ that is equal to the thickness TA of the first encapsulation portion 50. The thickness TQ of the external connection terminals 90A is greater than two times the thickness TW of the interconnect portions 80. The thickness TQ of the external connection terminals 90A is greater than or equal to three times the thickness TW of the interconnect portions 80. The thickness TQ of the external connection terminals 90A is less than or equal to four times the thickness TW of the interconnect portions 80.

The thickness TQ of the external connection terminals 90A is greater than or equal to 40 μm. The thickness TQ of the external connection terminals 90A is less than or equal to 70 μm. In the present embodiment, the thickness TQ of the external connection terminals 90A is approximately 55 μm.

As shown in FIGS. 3 and 4, the thermal pad 90B forms part of the electrical conductors 30 and is arranged to overlap the semiconductor element 20 as viewed in the z-direction. As shown in FIGS. 2 and 4, in the present embodiment, the thermal pad 90B is arranged in the center of the resin back surface 42. The thermal pad 90B is arranged to overlap the inner part 82B of the interconnect portion 82. The thermal pad 90B and the external connection terminals 90A are formed from the same material. The thermal pad 90B releases heat from the semiconductor element 20 to the outside of the encapsulation resin 40. As viewed in the z-direction, the thermal pad 90B is rectangular.

As shown in FIG. 3, the thermal pad 90B is electrically connected to the interconnect portion 82. The thermal pad 90B is covered by the interconnect portion 82 in the z-direction and thus does not project from the first encapsulation front surface 51 of the first encapsulation portion 50 toward the resin front surface 41. Also, the thermal pad 90B does not project from the first encapsulation back surface 52 (resin back surface 42) of the first encapsulation portion 50 in a direction away from the first encapsulation front surface 51. Therefore, the thermal pad 90B has a thickness TP that is equal to the thickness TA of the first encapsulation portion 50. In other words, the thickness TP of the thermal pad 90B is equal to the thickness TQ of the external connection terminals 90A. Thus, the pillar portions 90 are equal to each other in thickness T.

As shown in FIG. 2, the inner part 82B of the interconnect portion 82 is slightly greater than the thermal pad 90B in dimension in the x-direction. The inner part 82B is slightly greater than the thermal pad 90B in dimension in the y-direction. Thus, as viewed in the z-direction, the inner part 82B covers the entirety of the thermal pad 90B.

The thermal pad 90B has a dimension in the y-direction that is larger than the width-wise dimension of the outer part 82A of the interconnect portion 82 (dimension of the outer part 82A in the y-direction). The thermal pad 90B includes a slope 90BA at a location corresponding to the slope 82D of the inner part 82B. In the same manner as the slope 82D, as the slope 90BA extends from the first resin side surface 43 toward the second resin side surface 44, the slope 90BA is inclined toward the third resin side surface 45.

Each corner of the thermal pad 90B excluding the slope 90BA is a right angle. In other words, the thermal pad 90B includes a right-angled corner at a location corresponding to the position P1 of the interconnect portion 82 shown in FIG. 2.

In the present embodiment, the dimension of the thermal pad 90B in the x-direction is larger than the dimensions of the external connection terminal 90A in the x-direction and the y-direction. The dimension of the thermal pad 90B in the y-direction is larger than the dimensions of the external connection terminal 90A in the x-direction and the y-direction. Therefore, the thermal pad 90B is greater than the external connection terminal 90A in area as viewed in the z-direction. The thermal pad 90B is greater than the external connection terminal 90A in volume. In the present embodiment, the dimension of the thermal pad 90B in the x-direction is approximately 200 μm. The dimension of the thermal pad 90B in the y-direction is approximately 200 μm.

As shown in FIG. 4, the resin back surface 42 includes four corners, each of which includes a corner terminal 101. The corner terminals 101 extend through the first encapsulation portion 50 in the z-direction. Each corner terminal 101 is exposed from the resin back surface 42 and two resin side surfaces forming the corner. The corner terminals 101 and the external connection terminals 90A are formed from the same material. In the present embodiment, the corner terminals 101 are not electrically connected to the interconnect portions 80. In other words, the corner terminals 101 are not included in the electrical conductors 30. Although not shown, each corner terminal 101 has a thickness that is equal to the thickness TQ of the external connection terminals 90A.

As shown in FIG. 2, as viewed in the z-direction, corner interconnects 100 are arranged on the first encapsulation front surface 51 of the first encapsulation portion 50 to overlap the corner terminals 101 (refer to FIG. 4). The corner interconnects 100, which differ from the interconnect portions 80, are not electrically connected to the semiconductor element 20. Hence, the corner interconnects 100 are not included in the electrical conductors 30. The corner interconnects 100 and the interconnect portions 80 are formed from, for example, the same material. Although not shown, in the same manner as the interconnect portions 80, the corner interconnects 100 may have a stacking structure of a metal layer and a main interconnect layer.

As shown in FIG. 3, the conductive films 110 are arranged on portions of the external connection terminals 90A exposed from the encapsulation resin 40. The conductive films 110 cover the external connection terminals 90A and the exposed interconnect side surfaces 81 of the interconnect portions 80. Also, a conductive film 110 is arranged on a portion of the thermal pad 90B exposed from the resin back surface 42. The conductive films 110 are formed by, for example, electroless plating. In addition, although not shown in the drawings, conductive films 110 are arranged on portions of the corner terminals 101 exposed from the encapsulation resin 40.

### Material of Encapsulation Resin

The material of the encapsulation resin 40 will now be described.

Each of the first encapsulation portion 50 and the second encapsulation portion 60 of the encapsulation resin 40 is formed from an insulative material. Each of the first encapsulation portion 50 and the second encapsulation portion 60 is, for example, formed from a different material. In other words, the first encapsulation portion 50 is formed from a first material, and the second encapsulation portion 60 is formed from a second material differing from the first material. Each of the first encapsulation portion 50 and the second encapsulation portion 60 includes an epoxy resin.

The second material has a lower Young's modulus than the first material. In an example, the Young's modulus of the first material is greater than or equal to 20 GPa. The Young's modulus of the second material is less than 20 GPa.

In an example, each of the first material and the second material has a flexural strength that is greater than 70 MPa. In an example, each of the first material and the second material has a flexural strength that is greater than or equal to 80 MPa. The flexural strength of the first material is greater than the flexural strength of the second material and is, for example, greater than or equal to 90 MPa. The flexural strengths of the first material and the second material are measured, for example, in accordance with JIS K 6911.

It is preferred that the first material and the second material each have a linear expansion coefficient that is less than or equal to 10 ppm/° C. It is further preferred that the first material and the second material each have a linear expansion coefficient that is less than 10 ppm/° C. It is preferred that the difference in linear expansion coefficient between the first material and the second material is small. It is preferred that the difference in linear expansion coefficient between the first material and the second material is less than or equal to 1 ppm/° C. In an example, the linear expansion coefficient of the first material is approximately 9 ppm/° C. In an example, the linear expansion coefficient of the second material is approximately 8 ppm/° C.

In one of the first material and the second material, the epoxy resin is, for example, of a biphenyl type. In the other one of the first material and the second material, the epoxy resin is, for example, a biphenyl aralkyl epoxy resin containing biphenylene in the main backbone as a polycyclic aromatic resin. The first material and the second material may be any insulative materials as long as the Young's modulus of the second material is less than the Young's modulus of the first material.

The first encapsulation portion 50 and the second encapsulation portion 60 may each include a curing agent. The curing agent may be, for example, a melamine resin.

The first encapsulation portion 50 and the second encapsulation portion 60 may each include, for example, a filler that improves heat dissipation properties. The filler is formed from a material including, for example, silicon dioxide (SiO₂). The content ratio of the filler is, for example, in a range of 85 w % to 90 w %. In the present embodiment, the content ratio of the filler is approximately 86 w %.

For example, the first material has a higher Young's modulus than the second material and includes a biphenyl aralkyl epoxy resin as the epoxy resin, a melamine resin as the curing agent, and a filler. The Young's modulus of the first material is 21 GPa. The flexural strength of the first material is 85 MPa.

For example, the second material has a lower Young's modulus than the first material and includes a biphenyl epoxy resin as the epoxy resin, a melamine resin as the curing agent, and a filler. The Young's modulus of the second material is 18 GPa. The flexural strength of the second material is 95 MPa.

### Semiconductor Device Manufacturing Method

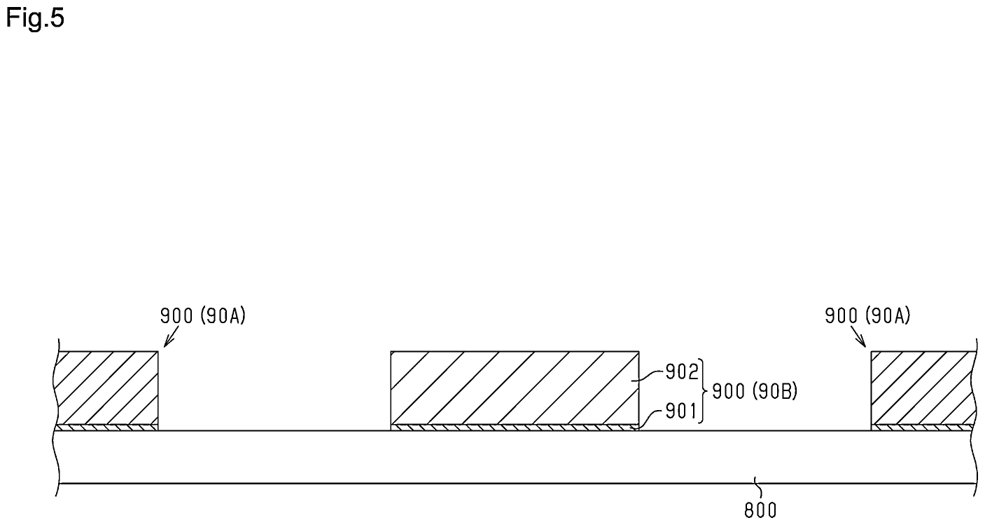

An example of a method for manufacturing the semiconductor device 10 will now be described with reference to FIGS. 5 to 14.

The method for manufacturing the semiconductor device 10 of the present embodiment includes a semiconductor wafer preparing step, a pillar forming step, a first encapsulation layer forming step, a grinding step, an interconnect layer forming step, a semiconductor element mounting step, a second encapsulation layer forming step, a wafer removing step, a half-cutting step, a conductive film forming step, and a singulating step. In the method for manufacturing the semiconductor device 10 of the present embodiment, the semiconductor wafer preparing step, the pillar forming step, the first encapsulation layer forming step, the grinding step, the interconnect layer forming step, the semiconductor element mounting step, the second encapsulation layer forming step, the wafer removing step, the half-cutting step, the conductive film forming step, and the singulating step are sequentially performed.

As shown in FIG. 5, in the semiconductor wafer preparing step, for example, a semiconductor wafer 800 that is formed from a monocrystalline Si material is prepared. In the pillar forming step, metal pillars 900 are formed on the semiconductor wafer 800.

The metal pillars 900 form the pillar portions 90 and the corner terminals 101. More specifically, the metal pillars 900 form the external connection terminals 90A, the thermal pad 90B, and the four corner terminals 101. The metal pillars 900 have a thickness that is greater than each of the thickness TQ of the external connection terminals 90A, the thickness TP of the thermal pad 90B, and the thickness of the corner terminals 101. The metal pillars 900 shown in FIGS. 5 to 14 form the external connection terminals 90A and the thermal pad 90B.

The metal pillars 900 are formed by, for example, electrolytic plating. More specifically, a seed layer 901 is formed on the semiconductor wafer 800. Then, the seed layer 901 undergoes photolithography to form a mask (not shown). The mask is removed after a plating metal 902 is formed in contact with the seed layer 901. Thus, each metal pillar 900 has a stacking structure of the seed layer 901 and the plating metal 902.

The seed layer 901 is formed on the semiconductor wafer 800 by, for example, sputtering. Then, for example, the seed layer 901 is covered by a photosensitive resist layer, and the resist layer undergoes exposure and development to form a mask having openings. Electrolytic plating in which the seed layer 901 is used as a conductive path is performed so that plating metal 902 deposits on the surface of the seed layer 901 exposed from the mask. The steps described above form the metal pillars 900. Subsequent to formation of the metal pillars 900, the mask is removed.

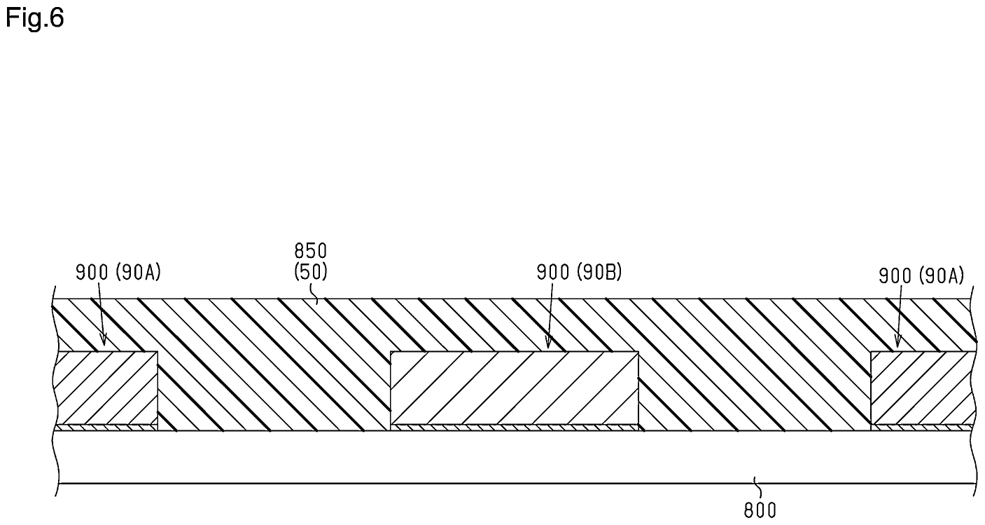

As shown in FIG. 6, in the first encapsulation layer forming step, a first encapsulation layer 850 is formed on the semiconductor wafer 800. The first encapsulation layer 850 is a resin layer that forms the first encapsulation portion 50 of the semiconductor device 10 and encapsulates the metal pillars 900 so that the metal pillars 900 are located between the first encapsulation layer 850 and the semiconductor wafer 800. The first encapsulation layer 850 is, for example, formed from a material including an epoxy resin. In an example, the first encapsulation layer 850 is formed from a material including a biphenyl aralkyl epoxy resin as the epoxy resin, a melamine resin as the curing agent, and a filler. Such a material has a Young's modulus of, for example, 21 GPa. The first encapsulation layer 850 is formed by, for example, compression molding. The thickness of the first encapsulation layer 850 shown in FIG. 6 is greater than the thickness TA of the first encapsulation portion 50.

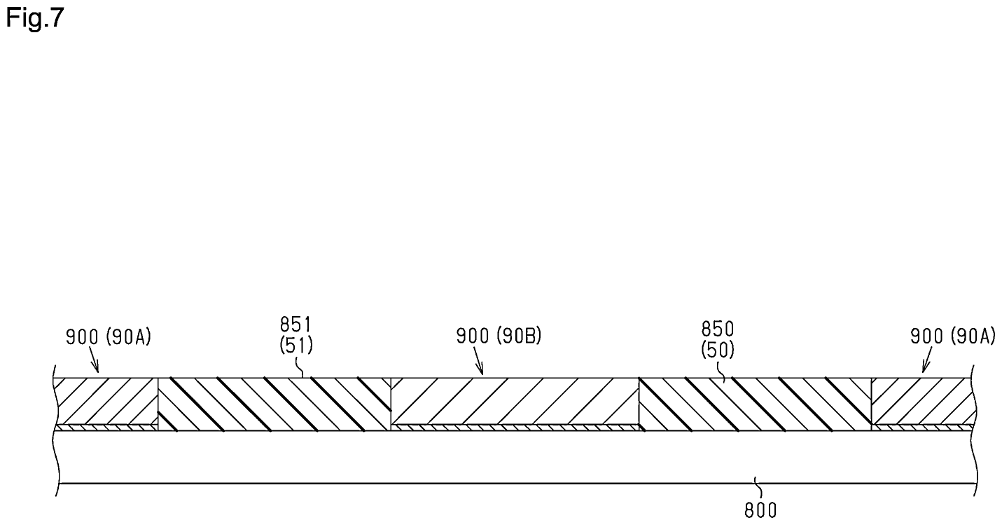

As shown in FIG. 7, in the grinding step, the first encapsulation layer 850 and the metal pillars 900 are ground. In the thickness-wise direction of the first encapsulation layer 850, the first encapsulation layer 850 and the metal pillars 900 are ground from the side opposite from the semiconductor wafer 800. As a result, in the thickness-wise direction of the first encapsulation layer 850, the metal pillars 900 are exposed from the first encapsulation layer 850. In this step, it is preferred that the thickness of the first encapsulation layer 850 is in a range of 60 μm to 90 μm. The thickness of the first encapsulation layer 850 is greater than the thickness TA of the first encapsulation portion 50. The thickness of the metal pillars 900 is greater than each of the thickness TQ of the external connection terminals 90A, the thickness TP of the thermal pad 90B, and the thickness of the corner terminals 101. The first encapsulation layer 850 includes an encapsulation front surface 851, which is a ground surface that is formed in the grinding step and defines the first encapsulation front surface 51 of the first encapsulation portion 50.

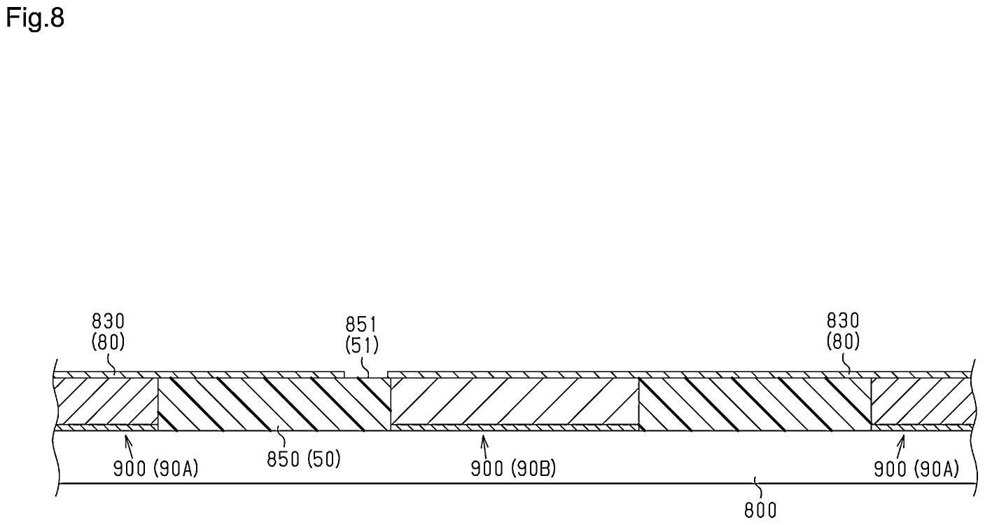

As shown in FIG. 8, in the interconnect layer forming step, an interconnect layer 830 is formed on the encapsulation front surface 851 of the first encapsulation layer 850 and the metal pillars 900 that have been ground. The interconnect layer 830 is a metal layer forming the interconnect portions 80 and the corner interconnects 100 (refer to FIG. 2) of the semiconductor device 10. Thus, the interconnect layer 830 is formed separately from the metal pillars 900.

The interconnect layer 830 is formed of a plating layer. Although not shown, the interconnect layer 830 includes a metal layer and a main interconnect layer.

The metal layer is formed by, for example, sputtering on the encapsulation front surface 851 of the first encapsulation layer 850 and a portion of the metal pillars 900 that have been ground. The metal layer includes, for example, a Ti layer and a Cu layer. In an example of a specific formation process, the Ti layer is formed on the encapsulation front surface 851 of the first encapsulation layer 850 and a portion of the metal pillars 900. The Cu layer is formed in contact with the Ti layer.

The metal layer undergoes photolithography to form a mask. In an example of a specific formation process, the metal layer is covered by a photosensitive resist layer, and the resist layer undergoes exposure and development to form a mask having openings. The openings in the mask correspond to locations where the interconnect portions 80 and the corner interconnect 100 (refer to FIG. 2) are formed.

In an example, the main interconnect layer is formed by electrolytic plating in which the metal layer is used as a conductive path so that plating metal deposits on the surface of the metal layer exposed from the openings of the mask. Subsequently, the mask is removed.

Next, the portion of the metal layer that does not overlap the main interconnect layer is removed. In an example, the main interconnect layer and the metal layer undergo photolithography to form a mask. Then, openings are formed in portions of the metal layer that do not overlap the main interconnect layer. The metal layer exposed from the openings in the mask is removed. Then, the mask is removed. The steps described above form the interconnect layer 830, which forms the interconnect portions 80 and the corner interconnects 100. The thickness of the interconnect layer 830 is equal to the thickness TW of the interconnect portions 80.

In this process, the first encapsulation layer 850 and the metal pillars 900 are reduced in thickness prior to formation of the interconnect layer 830. Thus, warpage of the semiconductor wafer 800 is limited after formation of the interconnect layer 830. This facilitates transportation of the semiconductor wafer 800 in a step subsequent to formation of the interconnect layer 830.

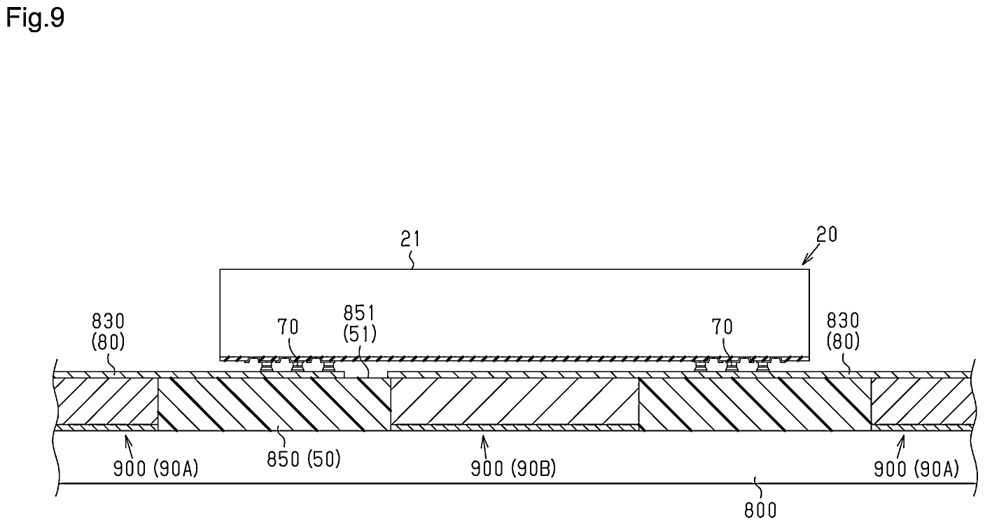

As shown in FIG. 9, in the semiconductor element mounting step, the semiconductor element 20 is mounted on the interconnect layer 830. More specifically, for example, electrolytic plating that uses the interconnect layer 830 as a conductive path is performed to form a protective layer. The protective layer is formed from, for example, Ni. Then, electric field plating is performed so that an alloy including Sn deposits on the protective layer as plating metal. This forms an interconnect-side bonding layer. Subsequently, a reflow process is performed to melt the interconnect-side bonding layer, thereby smoothing a rough surface of the interconnect-side bonding layer. The smoothing limits formation of voids when the interconnect-side bonding layer is bonded to the semiconductor element 20. The semiconductor element 20 is bonded to the interconnect-side bonding layer. That is, the semiconductor element 20 is mounted on the interconnect layer 830. The semiconductor element 20 is mounted by flip chip bonding (FCB).

In the mounting of the semiconductor element 20, for example, electrolytic plating is performed so that an alloy including Sn deposits as plating metal on the semiconductor element 20. This forms a solder layer (not shown). The solder layer is formed from, for example, the same material as that forming the interconnect-side bonding layer. In the same manner as the interconnect-side bonding layer, a reflow process is performed to smooth a surface of the solder layer of the semiconductor element 20.

Next, for example, a flux is applied to the solder layer of the semiconductor element 20, and then the solder layer of the semiconductor element 20 is mounted on the interconnect-side bonding layer using, for example, a flip-chip bonder. As a result, the semiconductor element 20 is temporarily attached to the interconnect-side bonding layer. A reflow process is performed so that the interconnect-side bonding layer and the solder layer of the semiconductor element 20 change phase to a liquid state. Then, the interconnect-side bonding layer and the solder layer of the semiconductor element 20 are cooled and solidified. As a result, the semiconductor element 20 is bonded to the interconnect-side bonding layer. Thus, the bonding layer pieces 70 are formed of the interconnect-side bonding layer and the solder layer of the semiconductor element 20.

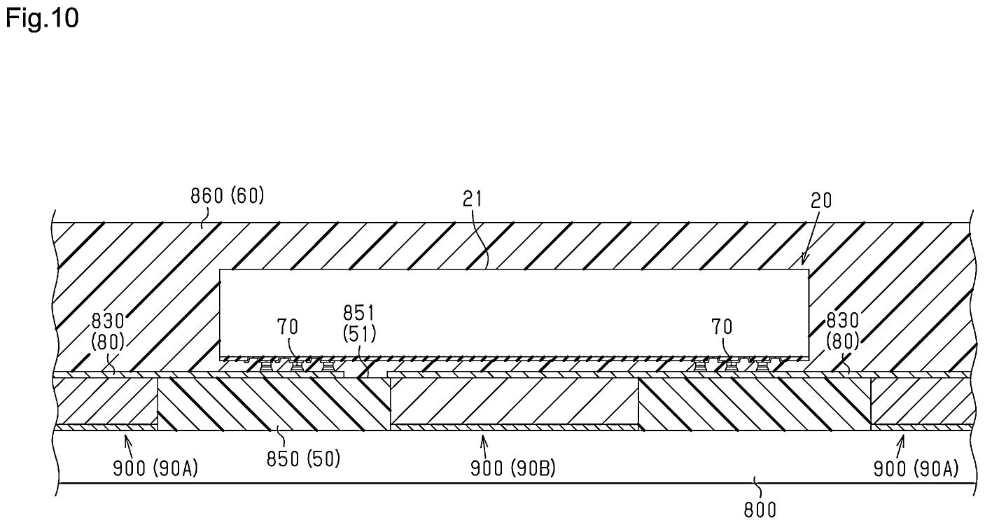

As shown in FIG. 10, in the second encapsulation layer forming step, a second encapsulation layer 860 is formed to encapsulate the semiconductor element 20. The second encapsulation layer 860 forms the second encapsulation portion 60 (refer to FIG. 3) of the encapsulation resin 40. The second encapsulation layer 860 and the first encapsulation layer 850 are formed from different materials. In an example, the second encapsulation layer 860 is formed from a material including a biphenyl epoxy resin as the epoxy resin, a melamine resin as the curing agent, and a filler. The Young's modulus of such a material is lower than that of the material forming the first encapsulation layer 850 and is, for example, 18 GPa. The second encapsulation layer 860 is formed by, for example, compression molding. The first encapsulation layer 850 and the second encapsulation layer 860 form the encapsulation resin 40. The second encapsulation layer 860 is greater in thickness than the first encapsulation layer 850. In other words, the thickness of the first encapsulation layer 850 is smaller than the thickness TB of the second encapsulation layer 860. The encapsulation front surface 851 of the first encapsulation layer 850 is the surface that has undergone grinding, and the material of the first encapsulation layer 850 differs from the material of the second encapsulation layer 860. Therefore, an interface is formed in the boundary between the first encapsulation layer 850 and the second encapsulation layer 860.

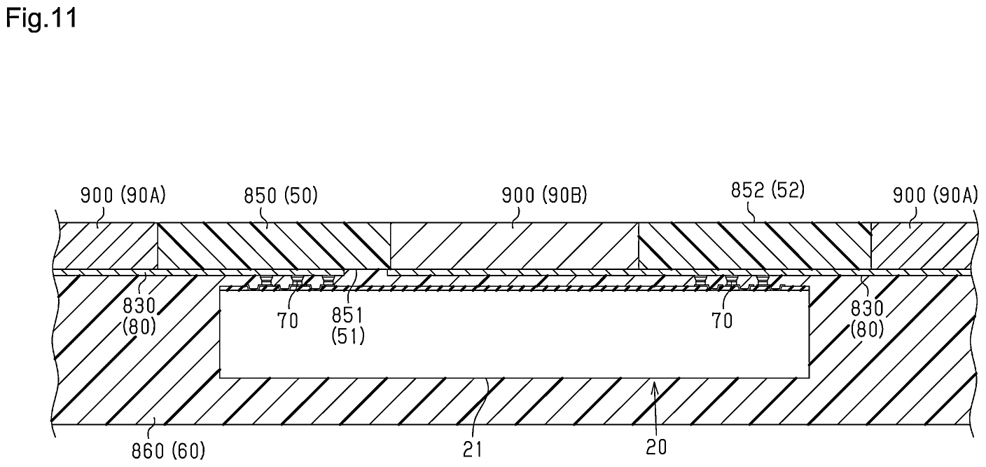

As shown in FIG. 11, in the wafer removing step, the semiconductor wafer 800 (refer to FIG. 10) is removed. The upper and lower sides in FIG. 10 are reversed in FIG. 11.

The semiconductor wafer 800 is removed from the first encapsulation layer 850 by, for example, grinding. When the semiconductor wafer 800 is removed from the first encapsulation layer 850, the first encapsulation layer 850 and the metal pillars 900 are partially removed in the thickness-wise direction of the first encapsulation layer 850. As a result, the seed layer 901 (refer to FIG. 5) is removed from the metal pillars 900. In addition, as a result of the removal of the semiconductor wafer 800 from the first encapsulation layer 850, the metal pillars 900 are exposed from the first encapsulation layer 850 at the side opposite from the second encapsulation layer 860. The first encapsulation layer 850 includes an encapsulation back surface 852 defining the first encapsulation back surface 52 of the first encapsulation portion 50.

In this step, the thickness of the first encapsulation layer 850 becomes equal to the thickness TA of the first encapsulation portion 50. The thickness of the metal pillars 900 becomes equal to the thickness TQ of the external connection terminals 90A, the thickness of the corner terminals 101 (refer to FIG. 4), and the thickness TP of the thermal pad 90B. In an example, the thickness of the first encapsulation layer 850 and the thickness of the metal pillars 900 are each in a range of 40 μm to 70 μm.

The means of removing the semiconductor wafer 800 may be changed in any manner. In an example, in the step of removing the semiconductor wafer 800, a separation film may be formed in advance, and the semiconductor wafer 800 may be removed by separation. Subsequent to separation of the semiconductor wafer 800, the first encapsulation layer 850 and the metal pillars 900 may be ground.

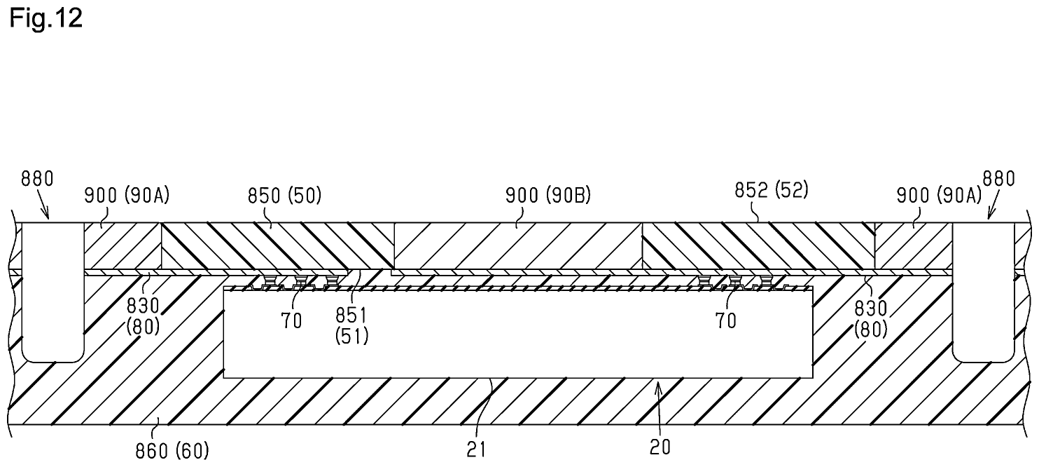

As shown in FIG. 12, in the half-cutting step, a first dicing blade is used to form grooves 880 by cutting the first encapsulation layer 850 and the metal pillars 900, corresponding to the external connection terminals 90A and the corner terminals 101, and partially cutting the second encapsulation layer 860 in the thickness-wise direction. The grooves 880 expose side surfaces of the metal pillars 900 from the first encapsulation layer 850 and side surfaces of the interconnect layer 830 from the second encapsulation layer 860. In the half-cutting step, the first encapsulation layer 850 forms the first encapsulation portion 50, the interconnect layer 830 forms the interconnect portions 80 and the corner interconnect 100 (refer to FIG. 2), and the metal pillars 900 form the external connection terminals 90A.

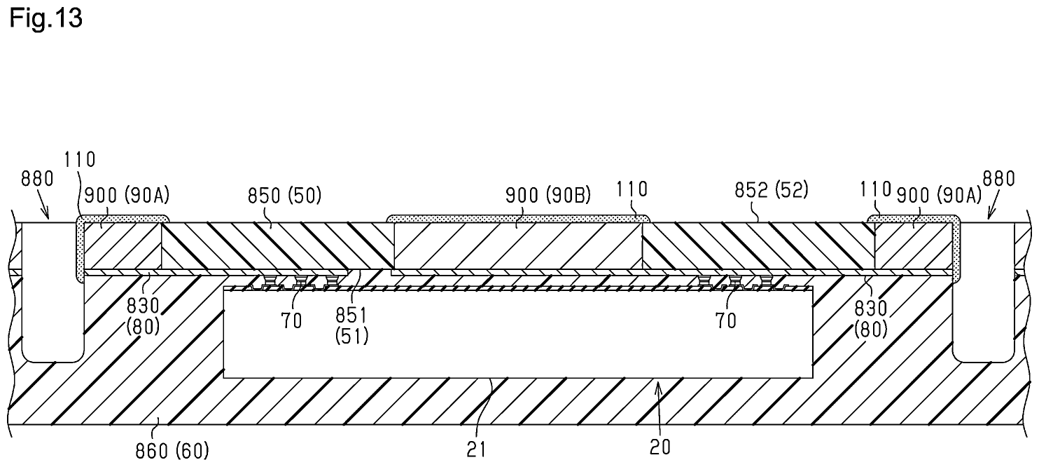

As shown in FIG. 13, in the conductive film forming step, the conductive films 110 are formed to cover the metal pillars 900, exposed from the first encapsulation layer 850, and the interconnect layer 830, exposed from the second encapsulation layer 860. The conductive films 110 are formed by, for example, electroless plating.

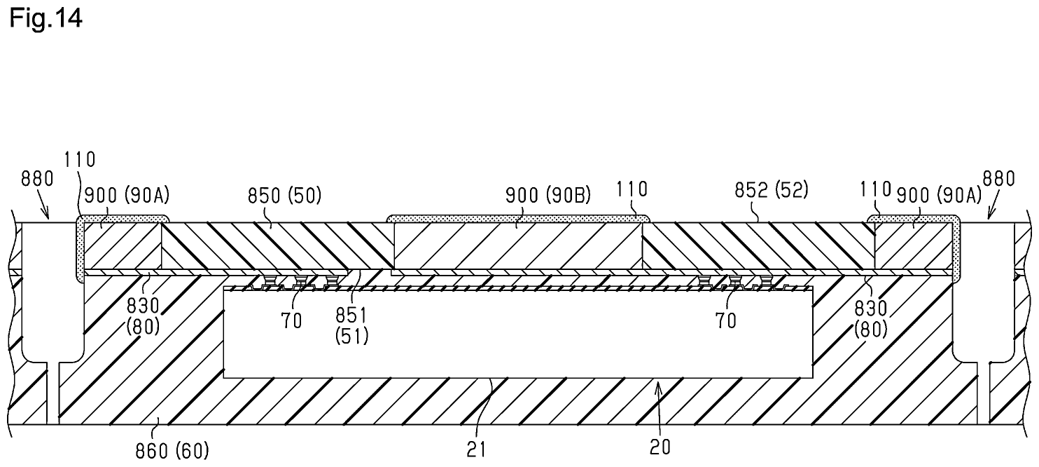

As shown in FIG. 14, in the singulating step, a second dicing blade having a smaller width than the first dicing blade is used to cut the second encapsulation layer 860. The second dicing blade cuts the second encapsulation layer 860 through the grooves 880. In the singulating step, the second encapsulation layer 860 forms the second encapsulation portion 60. The steps described above manufacture the semiconductor device 10.

The method for manufacturing the semiconductor device 10 may include an encapsulation layer grinding step that grinds the second encapsulation layer 860, which covers the element front surface 21 of the semiconductor element 20, after the second encapsulation layer 860 is formed in the second encapsulation layer forming step. This step decreases the thickness of the second encapsulation layer 860. Thus, the thickness of the second encapsulation portion 60 in the semiconductor device 10 is decreased. This allows for a reduction in the height of the semiconductor device 10.

### Operation

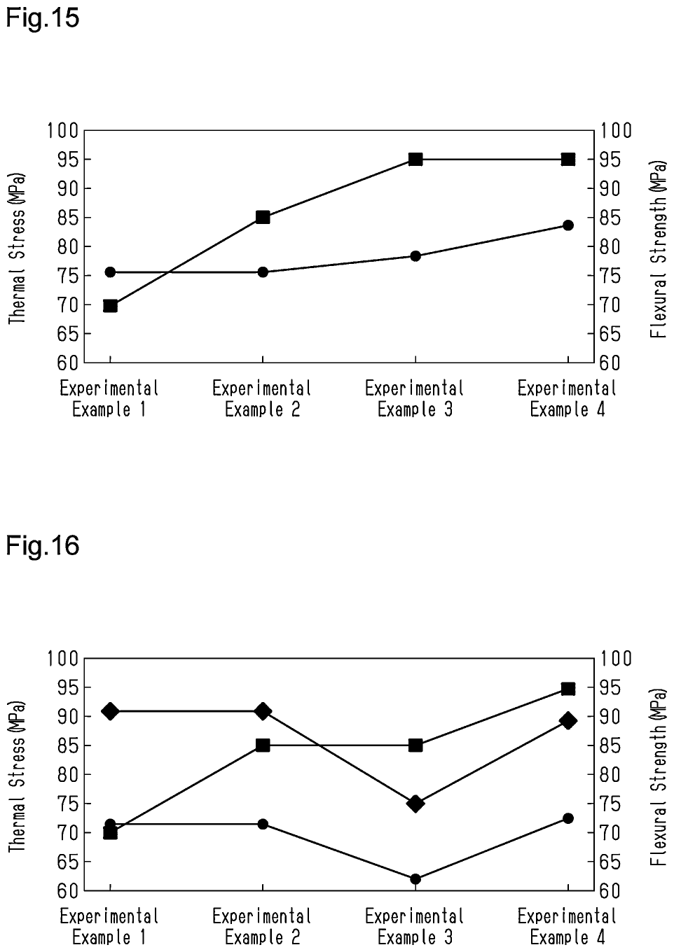

The operation of the present embodiment will now be described with reference to FIGS. 15 and 16.

FIG. 15 is a graph showing thermal stress in the pillar portions 90 and flexural strength of the first encapsulation portion 50 in experimental examples 1 to 4. In FIG. 15, a graph line with circle plots indicates thermal stress in the pillar portions 90, and a graph line with square plots indicates flexural strength of the first encapsulation portion 50. The thermal stress in the pillar portions 90 refers to thermal stress applied to the first encapsulation portion 50 in the side surfaces of the pillar portions 90 in contact with the first encapsulation portion 50. In FIG. 15, the thermal stress is obtained from a location where the pillar portions 90 have the maximum thermal stress. The location where the pillar portions 90 have the maximum thermal stress is the corner of the thermal pad 90B indicated by the position P1 in FIG. 2, where the thermal stress is applied to the first encapsulation portion 50.

FIG. 16 is a graph showing thermal stress in the interconnect portions 80 and flexural strength of the second encapsulation portion 60 in experimental examples 1 to 4. The thermal stress in the interconnect portions 80 refers to thermal stress applied to the second encapsulation portion 60 in the side surfaces of the interconnect portions 80 in contact with the second encapsulation portion 60. In FIG. 16, a graph line with rhomboid plots indicates thermal stress applied to the second encapsulation portion 60 in the corner of the interconnect portion 82 indicated by the position P1 shown in FIG. 2. In FIG. 16, a graph line with circle plots indicates thermal stress applied to the second encapsulation portion 60 in the center of the interconnect portion 82 in the y-direction indicated by the position P2 shown in FIG. 2. Thermal stress applied to the second encapsulation portion 60 in the corner of the interconnect portion 82 indicated by the position P1 shown in FIG. 2 is the maximum thermal stress applied to the second encapsulation portion 60. In the description hereafter, the thermal stress indicated by the graph line with rhomboid plots is referred to as a “maximum thermal stress.” The thermal stress indicated by the graph line with circle plots is referred to as a “specified thermal stress.” In FIG. 16, a graph line with square plots indicates flexural strength of the second encapsulation portion 60.

Referring to FIG. 2, the distal surface 82a of the interconnect portion 82, on which the position P1 and the position P2 are located, is opposite to the exposed interconnect side surface 81 of the interconnect portion 82. The dimension of the interconnect portion 82 in the x-direction is larger than the dimension of the other interconnect portions 80 in the x-direction. Thermal stress applied to the encapsulation resin 40 at the distal surface 82a is likely to be greater than thermal stress applied to the encapsulation resin 40 at the other interconnect portions 80.

In addition, as viewed in the z-direction, the thermal pad 90B, which is greater in volume than the external connection terminal 90A, overlaps the inner part 82B of the interconnect portion 82. The thermal pad 90B also applies thermal stress to the first encapsulation portion 50.

In particular, at the position P1, where the corner of the inner part 82B of the interconnect portion 82 and the corner of the thermal pad 90B are located, thermal stress applied to the encapsulation resin 40 is likely to be maximum in the encapsulation resin 40. That is, cracks are likely to be formed in the encapsulation resin 40 at the position P1. In other words, when cracks are not formed in the encapsulation resin 40 at the position P1, which receives the maximum thermal stress, it is considered that there is a low possibility that cracks will form in portions of the encapsulation resin 40 other than the position P1.

Experimental examples 1 to 4 shown in FIGS. 15 and 16 are as follows. In experimental examples 1, 2, and 4, the first material forming the first encapsulation portion 50 is the same as the second material forming the second encapsulation portion 60. In experimental example 3, the first material differs from the second material.

In experimental example 1, a semiconductor device includes an encapsulation resin including a first material and a second material that are formed from CEL-400ZHF40-SIN3-G (manufactured by Showa Denko Materials Co., Ltd.). In the first material and the second material of experimental example 1, CEL-400ZHF40-SIN3-G includes a material that includes a biphenyl aralkyl epoxy resin as the epoxy resin, a melamine resin as the curing agent, and SiO₂ as the filler and is processed at 150° C. as post mold curing. In experimental example 1, the first material and the second material each have a flexural strength of 70 MPa. In experimental example 1, the first material and the second material each have a Young's modulus of 18 GPa.

In experimental example 2, a semiconductor device includes an encapsulation resin including a first material and a second material that are formed from CEL-400ZHF40-SIN3-G. In the first material and the second material of experimental example 2, CEL-400ZHF40-SIN3-G includes a material that includes a biphenyl aralkyl epoxy resin as the epoxy resin, a melamine resin as the curing agent, and SiO₂ as the filler and is processed at 175° C. as post mold curing. In experimental example 2, the first material and the second material each have a flexural strength of 85 MPa. In experimental example 2, the first material and the second material each have a Young's modulus of 18 GPa.

In experimental example 3, a semiconductor device includes an encapsulation resin including a first material that is formed from CEL-400ZHF40-MF2G (manufactured by Showa Denko Materials Co., Ltd.) and a second material that is formed from CEL-400ZHF40-SIN3-G. In the second material of experimental example 3, CEL-400ZHF40-SIN3-G is processed at 175° C. as post mold curing. In experimental example 3, CEL-400ZHF40-MF2G includes a material including a biphenyl aralkyl epoxy resin as the epoxy resin, a melamine resin as the curing agent, and SiO₂ as the filler. In experimental example 3, the first material has a flexural strength of 95 MPa, and the second material has a flexural strength of 85 MPa. In experimental example 3, the first material has a Young's modulus of 21 GPa, and the second material has a Young's modulus of 18 GPa.

In experimental example 4, a semiconductor device includes an encapsulation resin including a first material and a second material that are formed from CEL-400ZHF40-MF2G. In experimental example 4, the first material and the second material each have a flexural strength of 95 MPa. In experimental example 4, the first material and the second material each have a Young's modulus of 21 GPa.

As shown in FIG. 15, when the first material has a low Young's modulus as in experimental examples 1 and 2, thermal stress in the pillar portions 90 is smaller than when the first material has a high Young's modulus as in experimental examples 3 and 4. In experimental examples 3 and 4, although the Young's modulus of the first material is the same, thermal stress is greater in experimental example 4 than in experimental example 3. This may be because the Young's modulus of the second material is greater in experimental example 4 than in experimental example 3.

As shown in FIG. 16, when the second material has a low Young's modulus as in experimental examples 1 to 3, the specified thermal stress is smaller than when the second material has a high Young's modulus as in experimental example 4. When the second material has a low Young's modulus as in experimental example 3, the maximum thermal stress is smaller than when the second material has a high Young's modulus as in experimental example 4.

In experimental example 3, the specified thermal stress is smaller than in experimental examples 1 and 2. In experimental example 3, the maximum thermal stress is smaller than in experimental examples 1 and 2. This may be because the Young's modulus and the flexural strength of the first material in experimental example 3 differ from those in experimental examples 1 and 2. More specifically, the Young's modulus of the first material is higher in experimental example 3 than in experimental examples 1 and 2. The flexural strength of the first material is greater in experimental example 3 than in experimental examples 1 and 2. In experimental example 3, the first encapsulation portion 50 is more resistant to deformation resulting from thermal stress. This reduces force generated by the deformation of the first encapsulation portion 50 and applied to the second encapsulation portion 60.

The inventor of the present application conducted a temperature cycle test on experimental examples 1 to 4 and found that cracks were formed in the first encapsulation portion 50 corresponding to the position P1 at 300 cycles in experimental example 1 and that cracks were formed in the first encapsulation portion 50 corresponding to the position P1 at 700 cycles in experimental examples 2 and 4. The inventor also found that cracks were not formed in the encapsulation resin 40 even after 2000 cycles in experimental example 3.

The results indicate that cracks are less likely to be formed in the first encapsulation portion 50 in experimental example 2 than in experimental example 1 because the flexural strength of the first material in experimental example 2 is greater than that in experimental example 1. The results also indicate that although in experimental examples 3 and 4, thermal stress is increased in the pillar portions 90 because of the high Young's modulus of the first material as compared to that in experimental example 1, cracks are less likely to be formed in the first encapsulation portion 50 in experimental examples 3 and 4 than in experimental example 1 because of the greater flexural strength of the first material in experimental examples 3 and 4.

As in experimental example 3, when the second material has a lower Young's modulus than the first material, thermal stress applied to the second encapsulation portion 60 at the interconnect portions 80 is decreased. Accordingly, in experimental example 3, force generated by deformation of the second encapsulation portion 60 caused by stress and acting to deform the first encapsulation portion 50 is decreased. Thus, deformation of the first encapsulation portion 50 is limited. Therefore, cracks are less likely to be formed in the first encapsulation portion 50 in experimental example 3 than in experimental examples 2 and 4.

### Advantages

The present embodiment has the following advantages.

(1-1) The semiconductor device 10 includes the semiconductor element 20 including the element front surface 21 and the element back surface 22 opposite to the element front surface 21, the electrical conductors 30 extending outward from a position opposed to the element back surface 22 beyond the element back surface 22 and electrically connected to the semiconductor element 20, and the encapsulation resin 40 including the first encapsulation portion 50 on which the electrical conductors 30 are arranged and the second encapsulation portion 60 encapsulating the electrical conductors 30 and the semiconductor element 20 in cooperation with the first encapsulation portion 50. The first encapsulation portion 50 is formed from the first material. The second encapsulation portion 60 is formed from the second material. The second material has a lower Young's modulus than the first material.

In this structure, as described above in the Operation section, since the second material has a lower Young's modulus than the first material, the specified thermal stress and the maximum thermal stress applied to the second encapsulation portion 60 are both decreased. Thus, even when the temperature of the semiconductor device 10 is changed, cracks are less likely to be formed in the encapsulation resin 40.

(1-2) The flexural strength of the first material is greater than or equal to 90 MPa. The flexural strength of the second material is greater than or equal to 80 MPa.

In this structure, deformations of both the first encapsulation portion 50 and the second encapsulation portion 60 are limited. Thus, cracks caused by deformations of the first encapsulation portion 50 and the second encapsulation portion 60 are less likely to be formed in the encapsulation resin 40.

(1-3) The electrical conductors 30 are formed of a plating layer.

With this structure, the electrical conductors 30 are reduced in thickness as compared to a structure in which the electrical conductors 30 are formed of, for example, a thin metal plate such as a lead frame. This allows for a reduction in the height of the semiconductor device 10.

(1-4) The thickness TW of the interconnect portions 80 of the electrical conductors 30 is less than or equal to 20 μm.

This structure decreases the thickness TW of the interconnect portions 80, thereby obtaining the semiconductor device 10 having a low profile. However, when the thickness TW of the interconnect portions 80 is decreased, stress applied to the second encapsulation portion 60 is increased in the interconnect portions 80. In this regard, in the present embodiment, the second material has a lower Young's modulus than the first material. Thus, the specified thermal stress and the maximum thermal stress are decreased. Thus, even when the thickness TW of the interconnect portions 80 is decreased, formation of cracks in the encapsulation resin 40 is limited.

(1-5) When the thickness TA of the first encapsulation portion 50 is less than 40 μm, the shape of the semiconductor element 20 and the shape of the interconnect portions 80 may be transparently seen from the first encapsulation back surface 52 of the first encapsulation portion 50. In addition, the anchoring strength of the pillar portions 90 in the first encapsulation portion 50 is decreased.

When the thickness TA of the first encapsulation portion 50 is greater than 70 μm, in the process of manufacturing the semiconductor device 10, the metal pillars 900, which form the pillar portions 90, are increased in thickness. This causes warpage of the semiconductor wafer 800. As a result, it is difficult to transport the semiconductor wafer 800 to a device for forming the interconnect layer 830.

In this regard, in the present embodiment, the thickness TA of the first encapsulation portion 50 is in a range of 40 μm to 70 μm. This avoids the transparency of the shape of the semiconductor element 20 and the shape of the interconnect portions 80 and the decrease in the anchoring strength of the pillar portions 90 in the first encapsulation portion 50. The semiconductor device 10 is readily manufactured.

(1-6) Each of the first material and the second material has a flexural strength that is greater than 70 MPa.

In this structure, deformations of the first encapsulation portion 50 and the second encapsulation portion 60 are limited as compared to a structure in which the flexural strength of each of the first material and the second material is less than 70 MPa. Thus, cracks are less likely to be formed in the encapsulation resin 40.

### Second Embodiment

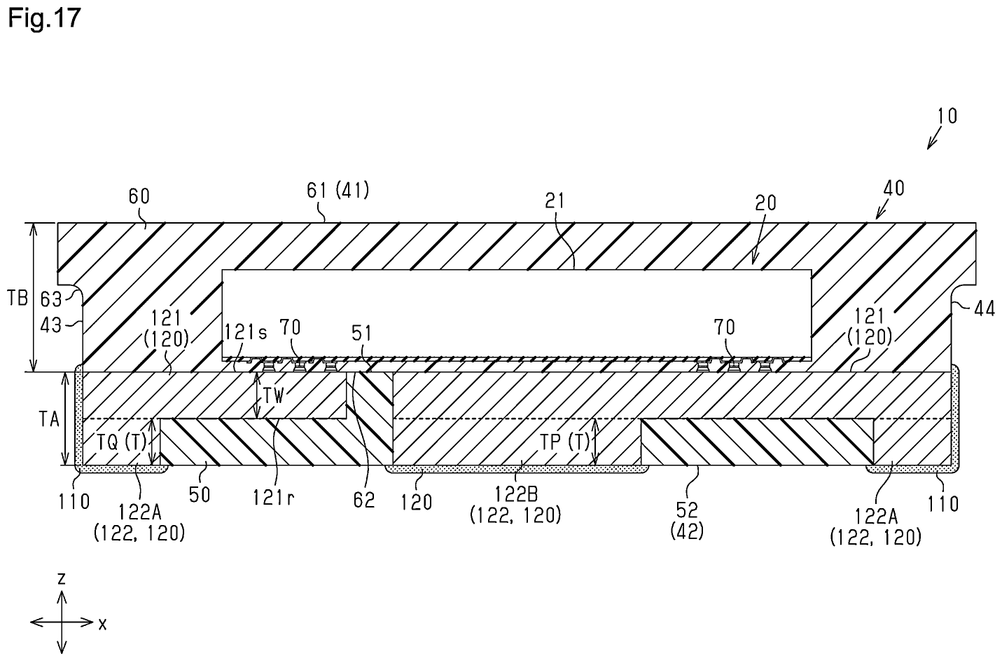

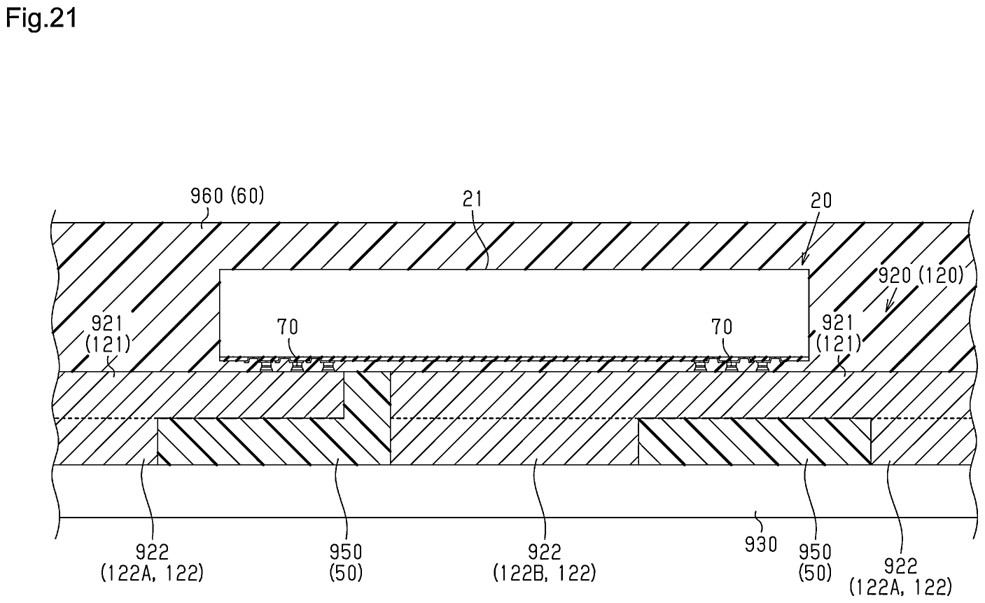

A second embodiment of a semiconductor device 10 will now be described with reference to FIGS. 17 and 21. The semiconductor device 10 of the present embodiment differs from the semiconductor device 10 of the first embodiment in the structure of an electrical conductor. In the description below, the same reference characters are given to those components that are the same as the corresponding components of the semiconductor device 10 of the first embodiment. Such components will not be described in detail.

### Structure of Semiconductor Device

As shown in FIG. 17, the semiconductor device 10 of the present embodiment includes an electrical conductor 120 formed of a lead frame instead of the electrical conductors 30 (refer to FIG. 3). The electrical conductor 120 extends outward from a position opposed to the element back surface 22 of the semiconductor element 20 beyond the element back surface 22. The electrical conductor 120 is electrically connected to the semiconductor element 20. More specifically, the semiconductor element 20 is bonded to the electrical conductor 120 by the bonding layer pieces 70.

The electrical conductor 120 is, for example, a thin metal plate formed of, for example, Cu or a Cu alloy. The Cu alloy includes Cu as a main component and is, for example, a Cu—Fe-based alloy or a Cu-zirconium (Zr)-based alloy. The electrical conductor 120 may be formed from any material. The material may be metal (e.g., 42Alloy to which Cu is added) including, for example, Cu as a minor component and metal other than Cu such as iron (Fe) as a main component. The electrical conductor 120 may be formed from high purity Cu of 95% or more, high purity Cu of 99.99% (4N) or more, or high purity Cu of 99.999% (6N) or more. The electrical conductor 120 may be formed of a thin metal plate of, for example, Fe—Ni-based alloy (iron-nickel alloy). In other words, the electrical conductor 120 may be formed from metal excluding Cu.

The electrical conductor 120 is arranged on the first encapsulation portion 50. The conductive films 110 are formed on surfaces of the electrical conductor 120 exposed from the first encapsulation portion 50. The structure of the conductive films 110 is the same as those in the first embodiment.

The electrical conductor 120 includes interconnect portions 121 extending in a direction orthogonal to the z-direction and pillar portions 122 extending from the interconnect portions 121 toward the first encapsulation back surface 52 of the first encapsulation portion 50. In the present embodiment, the interconnect portions 121 and the pillar portions 122 are formed integrally. The maximum thickness of the electrical conductor 120 is greater than or equal to 100 μm. In the present embodiment, the maximum thickness of the electrical conductor 120 is equal to a thickness TA of the first encapsulation portion 50. Hence, the thickness TA of the first encapsulation portion 50 is greater than the thickness TA of the first encapsulation portion 50 in the first embodiment. The thickness TA of the first encapsulation portion 50 is greater than or equal to 100 μm. The thickness TA of the first encapsulation portion 50 is smaller than the thickness TB of the second encapsulation portion 60 in the same manner as the first embodiment.

The interconnect portions 121 include an interconnect front surface 121s facing a same direction as the first encapsulation front surface 51 of the first encapsulation portion 50 and an interconnect back surface 121r opposite to the interconnect front surface 121s. The interconnect front surface 121s is flush with the first encapsulation front surface 51. In other words, the interconnect front surface 121s is flush with the interface, which is the boundary between the first encapsulation portion 50 and the second encapsulation portion 60. The interconnect back surface 121r is in contact with the first encapsulation portion 50. The thickness TW of the interconnect portions 121 is approximately ½ of the thickness TA of the first encapsulation portion 50. Thus, the thickness TW of the interconnect portions 121 in the present embodiment is greater than the thickness TW of the interconnect portions 80 in the first embodiment.

The pillar portions 122 extend from the interconnect back surface 121r in a direction away from the interconnect front surface 121s. The pillar portions 122 include external connection terminals 122A and a thermal pad 122B. The external connection terminals 122A are located outward from the semiconductor element 20 as viewed in the z-direction. The external connection terminals 122A are arranged in the same manner as the external connection terminals 90A in the first embodiment. As viewed in the z-direction, the thermal pad 122B is arranged to overlap the semiconductor element 20. The thermal pad 122B is arranged in the same manner as the thermal pad 90B in the first embodiment. In the present embodiment, the pillar portions 122 have a thickness T that is equal to the thickness TW of the interconnect portions 121. The thickness TQ of the external connection terminals 122A and the thickness TP of the thermal pad 122B are equal to the thickness TW of the interconnect portions 121. The material forming the first encapsulation portion 50 and the material forming the second encapsulation portion 60 are the same as those in the first embodiment.

### Semiconductor Device Manufacturing Method

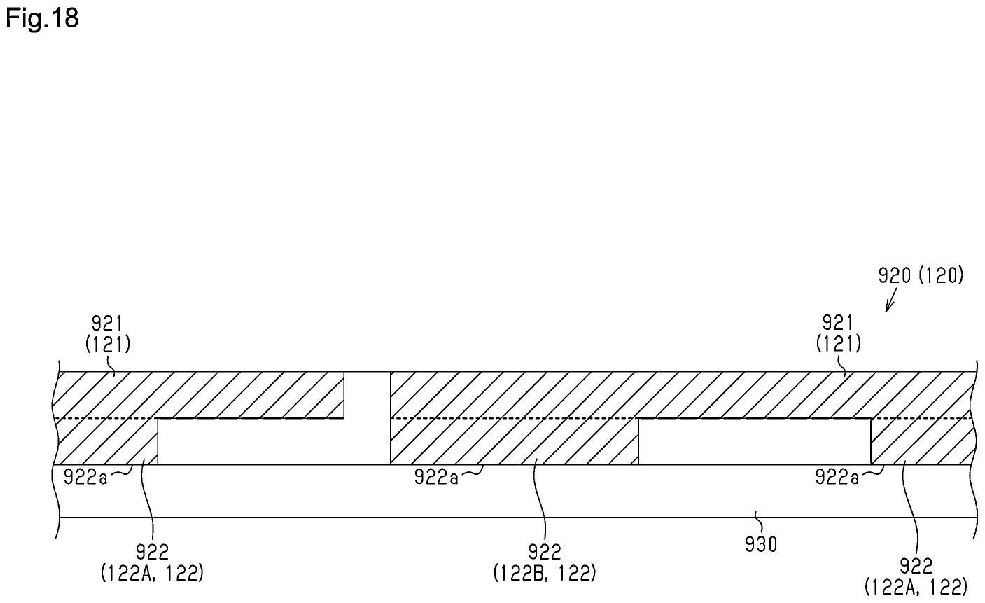

An example of a method for manufacturing the semiconductor device 10 of the present embodiment will be described with reference to FIGS. 18 to 21.

The method for manufacturing the semiconductor device 10 of the present embodiment includes an electrical conductor preparing step, a first encapsulation layer forming step, a semiconductor element mounting step, a second encapsulation layer forming step, a half-cutting step, a conductive film forming step, and a singulating step. In the method for manufacturing the semiconductor device 10 of the present embodiment, the electrical conductor preparing step, the first encapsulation layer forming step, the semiconductor element mounting step, the second encapsulation layer forming step, the half-cutting step, the conductive film forming step, and the singulating step are sequentially performed.

As shown in FIG. 18, in the electrical conductor preparing step, an electrical conductor 920 is prepared. The electrical conductor 920 forms the electrical conductor 120. The electrical conductor 920 is a thin metal plate formed from Cu or a Cu alloy and is formed by, for example, pressing. The electrical conductor 920 includes interconnect portions 921 and pillar portions 922. The interconnect portions 921 correspond to the interconnect portions 121 of the electrical conductor 120. The pillar portions 922 correspond to the pillar portions 122 of the electrical conductor 120.

Support tape 930 is applied to the electrical conductor 920 to support the electrical conductor 920. More specifically, the support tape 930 is applied to distal surfaces 922a of the pillar portions 922 of the electrical conductor 920. The support tape 930 is formed from, for example, a resin material.

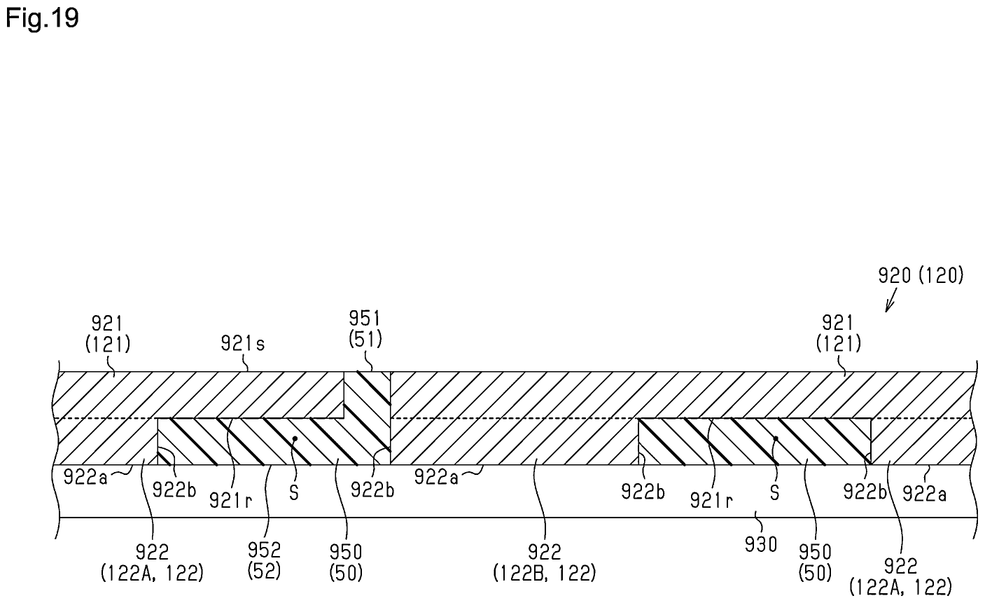

As shown in FIG. 19, in the first encapsulation layer forming step, a resin material fills empty spaces S surrounded by the support tape 930, interconnect back surfaces 921r of the interconnect portions 921, and side surfaces 922b of the pillar portions 922. This forms a first encapsulation layer 950. The first encapsulation layer 950 is formed from the same material as that forming the first encapsulation layer 850 of the first embodiment. The first encapsulation layer 950 is formed by, for example, transfer molding. As a result, the first encapsulation layer 950 includes an encapsulation front surface 951 that is flush with an interconnect front surface 921s of the interconnect portion 921. The first encapsulation layer 950 includes an encapsulation back surface 952 that is flush with the distal surface 922a of the pillar portion 922.

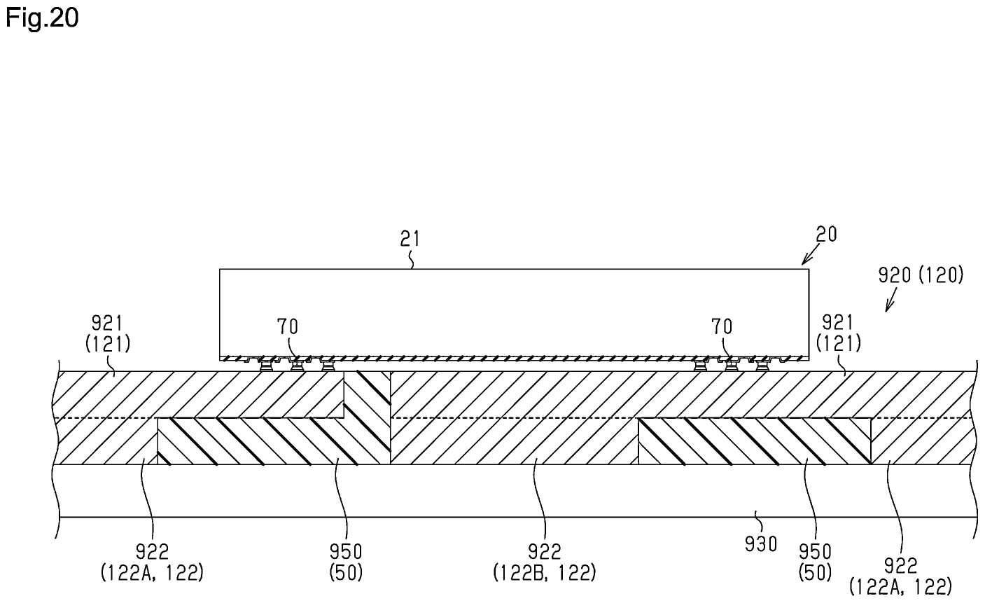

As shown in FIG. 20, in the semiconductor element mounting step, the semiconductor element 20 is mounted on the interconnect portion 921 via the bonding layer pieces 70. The process of mounting the semiconductor element 20 is the same as that of the first embodiment.

As shown in FIG. 21, in the second encapsulation layer forming step, a second encapsulation layer 960 is formed to encapsulate the semiconductor element 20. The second encapsulation layer 960 is formed from the same material as the second encapsulation layer 860 of the first embodiment. The second encapsulation layer 960 is formed by, for example, transfer molding. After the second encapsulation layer forming step is performed, the support tape 930 is removed.

Although not shown, in the half-cutting step, a first dicing blade is used to cut the first encapsulation layer 950 and the pillar portions 922 and partially cut the second encapsulation layer 960. In the conductive film forming step, the conductive films 110 are formed on the pillar portions 922, which are exposed from the first encapsulation layer 950 in the half-cutting step. The process for forming the conductive films 110 is the same as that of the first embodiment. In the singulating step, a second dicing blade having a smaller width than the first dicing blade is used to cut the second encapsulation layer 960. The process of cutting the second encapsulation layer 960 is the same as the first embodiment. The steps described above manufacture the semiconductor device 10. The semiconductor device 10 of the present embodiment has the same advantages as (1-1), (1-2), and (1-6) of the first embodiment.

### Modified Examples

The embodiments described above may be modified as follows. The embodiments described above and the modified examples described below can be combined as long as the combined modifications remain technically consistent with each other.

In the first embodiment, the structure of the interconnect portions 80 may be changed in any manner. In an example, the interconnect portion 82 may be omitted from the interconnect portions 80. That is, the thermal pad 90B does not have to be electrically connected to the interconnect portions 80.

In the first embodiment, the thickness TW of the interconnect portions 80 may be changed in any manner. In an example, the thickness TW of the interconnect portions 80 may be greater than or equal to 30 μm. The thickness TW of the interconnect portions 80 is, for example, less than or equal to 100 μm. The thickness TW of the interconnect portions 80 is, for example, in a range of 30 μm to 60 μm. This structure increases the area of side surfaces of the interconnect portions 80, thereby decreasing stress applied to the second encapsulation portion 60 in the interconnect portions 80. Thus, cracks are less likely to be formed in the encapsulation resin 40.

In the first embodiment, the thermal pad 90B may be used as an external connection terminal. More specifically, when the semiconductor device 10 is mounted on a circuit substrate, the thermal pad 90B may be electrically connected to the circuit substrate.

In the first embodiment, the conductive film 110 may be omitted from the thermal pad 90B.

In the first embodiment, the thermal pad 90B may be omitted from the pillar portions 90. When the thermal pad 90B is omitted, the inner part 82B and the joining part 82C may both be omitted from the interconnect portion 82. The corner terminals 101 may be omitted from the semiconductor device 10. When the corner terminals 101 are omitted, the corner interconnect 100 may also be omitted. In the second embodiment, the thermal pad 122B may be omitted from the pillar portions 122.

In the first embodiment, the external connection terminals 90A may be arranged so as not to be exposed from side surfaces of the first encapsulation portion 50. In the second embodiment, the external connection terminals 122A may be arranged so as not to be exposed from side surfaces of the first encapsulation portion 50. In other words, the external connection terminals 90A (122A) may be arranged to be exposed from only the first encapsulation back surface 52 of the first encapsulation portion 50.

In the second embodiment, the thermal pad 122B of the electrical conductor 120 may be used as an external connection terminal. More specifically, when the semiconductor device 10 is mounted on a circuit substrate, the thermal pad 122B may be electrically connected to the circuit substrate.

In the second embodiment, the conductive film 110 may be omitted from the thermal pad 122B.

In the second embodiment, the structure of the electrical conductor 120 may be changed in any manner. In an example, the thermal pad 122B may be arranged separately from the electrical conductor 120. That is, the thermal pad 122B does not have to be electrically connected to the electrical conductor 120. In this case, the thermal pad 122B may extend through the first encapsulation portion 50 in the z-direction.

In the second embodiment, the thickness TW of the interconnect portions 121 and the thickness T of the pillar portions 122 may be changed in any manner. In an example, the thickness T of the pillar portions 122 may be greater than the thickness TW of the interconnect portions 121 or may be smaller than the thickness TW of the interconnect portions 121.

In the second embodiment, in the electrical conductor preparing step, the conductive films 110 may be formed in advance on the distal surfaces 922a of the pillar portions 922 of the electrical conductor 920. In this case, the encapsulation back surface 952 of the first encapsulation layer 950, which is formed in the first encapsulation layer forming step, is flush with the conductive films 110. In the half-cutting step, the conductive films 110 do not have to be formed on side surfaces of the pillar portions 922 exposed from the first encapsulation layer 950.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In this specification, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### Clause 1

A semiconductor device (10), including:
a semiconductor element (20) including an element front surface (21) and an element back surface (22) opposite to the element front surface (21);
an electrical conductor (30) including an interconnect portion (80) and a pillar portion (90), the interconnect portion (80) extending outward from a position opposed to the element back surface (22) beyond the element back surface (22) as viewed from the element front surface (21) and electrically connected to the semiconductor element (20), and the pillar portion (90) extending with respect to the interconnect portion (80) in a direction away from the semiconductor element (20); and
an encapsulation resin (40) including a first encapsulation portion (50) on which the electrical conductor (30) is arranged and a second encapsulation portion (60) that encapsulates the electrical conductor (30) and the semiconductor element (20) in cooperation with the first encapsulation portion (50), in which
the first encapsulation portion (50) is formed from a first material,
the second encapsulation portion (60) is formed from a second material, and
the second material has a lower Young's modulus than the first material.

### Clause 2

The semiconductor device according to clause 1, in which the first material has a greater flexural strength than the second material.

### Clause 3

The semiconductor device according to clause 2, in which each of the first material and the second material has a flexural strength that is greater than 70 MPa.

### Clause 4

The semiconductor device according to clause 3, in which the flexural strength of the first material is greater than or equal to 90 MPa, and the flexural strength of the second material is greater than or equal to 80 MPa.

### Clause 5

The semiconductor device according to any one of clauses 1 to 4, in which the first material has a Young's modulus of 21 GPa, and the second material has a Young's modulus of 18 GPa.

### Clause 6

The semiconductor device according to any one of clauses 1 to 5, in which a thickness (TA) of the first encapsulation portion (50) is less than a thickness (TB) of the second encapsulation portion (60).

### Clause 7

The semiconductor device according to any one of clauses 1 to 6, in which the electrical conductor (30) includes a plating layer.

### Clause 8

The semiconductor device according to any one of clauses 1 to 7, in which the pillar portion (90) includes a thermal pad (90B).

### Clause 9

The semiconductor device according to any one of clauses 1 to 8, in which the pillar portion (90) includes an external connection terminal (90A) located outward from the semiconductor element (20) as viewed in a thickness-wise direction (z-direction) of the encapsulation resin (40).

### Clause 10

The semiconductor device according to any one of clauses 7 to 9, in which
an interface (51, 62) is formed in a boundary between the first encapsulation portion (50) and the second encapsulation portion (60),
the interconnect portion (80) includes an interconnect front surface (80s) facing a same direction as the element front surface (21) and an interconnect back surface (80r) opposite to the interconnect front surface (80s), and
in a thickness-wise direction (z-direction) of the encapsulation resin (40), the interconnect front surface (80s) is located closer to the semiconductor element (20) than the interface is, and the interconnect back surface (80r) is flush with the interface (51, 62).

### Clause 11

The semiconductor device according to any one of clauses 7 to 10, in which the interconnect portion (80) has a thickness (TW) that is less than or equal to 20 μm.

### Clause 12

The semiconductor device according to any one of clauses 1 to 6, in which the electrical conductor (120) includes a lead frame.

### Clause 13

The semiconductor device according to clause 12, in which
an interface (51, 62) is formed in a boundary between the first encapsulation portion (50) and the second encapsulation portion (60),
the interconnect portion (121) includes an interconnect front surface (121s) facing a same direction as the element front surface, and
the interconnect front surface (121s) is flush with the interface.

### Clause 14

A method for manufacturing a semiconductor device, the method including:
forming a metal pillar (900) by electrolytic plating;
forming a first encapsulation layer (850) from an insulating material to encapsulate the metal pillar (900);
forming an interconnect layer (830) on the first encapsulation layer (850) by electrolytic plating;
mounting a semiconductor element (20) on the interconnect layer (830); and
forming a second encapsulation layer (860) from an insulating material to encapsulate the interconnect layer (830) and the semiconductor element (20) in cooperation with the first encapsulation layer (850), in which
the first encapsulation layer (850) is formed from a first material,
the second encapsulation layer (860) is formed from a second material, and
the second material has a lower Young's modulus than the first material.

### Clause 15

The method according to clause 14, in which the first encapsulation layer (850) and the second encapsulation layer (860) are formed by compression molding.

### Clause 16

A method for manufacturing a semiconductor device, the method including:
preparing an electrical conductor (920) formed of a thin metal plate;
forming a first encapsulation layer (850) from an insulating material to encapsulate the electrical conductor (920);
mounting a semiconductor element (20) on the interconnect layer (920); and
forming a second encapsulation layer (860) from an insulating material to encapsulate the semiconductor element (20), in which
the first encapsulation layer (850) is formed from a first material,
the second encapsulation layer (860) is formed from a second material, and
the second material has a lower Young's modulus than the first material.

### Clause 17

The method according to clause 16, in which the first encapsulation layer (850) and the second encapsulation layer (860) are formed by transfer molding.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A semiconductor device, comprising:
a semiconductor element including an element front surface and an element back surface opposite to the element front surface;
an electrical conductor including an interconnect portion and a pillar portion, the interconnect portion extending outward from a position opposed to the element back surface beyond the element back surface as viewed from the element front surface and electrically connected to the semiconductor element, and the pillar portion extending with respect to the interconnect portion in a direction away from the semiconductor element; and
an encapsulation resin including a first encapsulation portion on which the electrical conductor is arranged and a second encapsulation portion that encapsulates the electrical conductor and the semiconductor element in cooperation with the first encapsulation portion, wherein
the first encapsulation portion is formed from a first material,
the second encapsulation portion is formed from a second material, and
the second material has a lower Young's modulus than the first material.

2. The semiconductor device according to claim 1, wherein the first material has a greater flexural strength than the second material.

3. The semiconductor device according to claim 2, wherein each of the first material and the second material has a flexural strength that is greater than 70 MPa.

4. The semiconductor device according to claim 3, wherein
the flexural strength of the first material is greater than or equal to 90 MPa, and
the flexural strength of the second material is greater than or equal to 80 MPa.

5. The semiconductor device according to claim 1, wherein
the first material has a Young's modulus of 21 GPa, and
the second material has a Young's modulus of 18 GPa.

6. The semiconductor device according to claim 1, wherein a thickness of the first encapsulation portion is less than a thickness of the second encapsulation portion.

7. The semiconductor device according to claim 1, wherein the electrical conductor includes a plating layer.

8. The semiconductor device according to claim 1, wherein the pillar portion includes a thermal pad.

9. The semiconductor device according to claim 1, wherein the pillar portion includes an external connection terminal located outward from the semiconductor element as viewed in a thickness-wise direction of the encapsulation resin.

10. The semiconductor device according to claim 7, wherein
an interface is formed in a boundary between the first encapsulation portion and the second encapsulation portion,
the interconnect portion includes an interconnect front surface facing a same direction as the element front surface and an interconnect back surface opposite to the interconnect front surface, and
in a thickness-wise direction of the encapsulation resin, the interconnect front surface is located closer to the semiconductor element than the interface is, and the interconnect back surface is flush with the interface.

11. The semiconductor device according to claim 7, wherein the interconnect portion has a thickness that is less than or equal to 20 km.

12. The semiconductor device according to claim 1, wherein the electrical conductor includes a lead frame.

13. The semiconductor device according to claim 12, wherein
an interface is formed in a boundary between the first encapsulation portion and the second encapsulation portion,
the interconnect portion includes an interconnect front surface facing a same direction as the element front surface, and
the interconnect front surface is flush with the interface.
